(19) United States
(12) Patent Application Publication
(10) Pub. No.: US 2019/0280216 A1
(43) Pub. Date: Sep. 12, 2019

(54) ORGANIC ELECTROLUMINESCENT ELEMENT, DISPLAY AND LIGHTING DEVICE

(71) Applicant: Konica Minolta, Inc., Tokyo (JP)

(72) Inventors: Satomi KAWABE, Hachioji-shi, Tokyo (JP); Kunio TANI, Hachioji-shi, Tokyo (JP); Hiroto ITO, Midori-ku, Yokohama-shi, Kanagawa (JP)

(21) Appl. No.: 16/302,459

(22) PCT Filed: Apr. 6, 2017
(86) PCT No.: PCT/JP2017/014365

§ 371 Date: Nov. 16, 2018

(30) Foreign Application Priority Data
May 19, 2016 (JP) 2016-100865

(51) Int. Cl. H01L 51/00; H01L 51/50

(52) U.S. Cl. CPC H01L 51/0072; H01L 51/0054; H01L 51/0073; H01L 51/0074; H01L 51/0067; H01L 51/0085; H01L 51/524; H01L 51/5016; H01L 51/5056; H01L 51/5072; H01L 51/5092; H01L 51/5096; H01L 51/006

(57) ABSTRACT

Provided are an organic electroluminescent element having a long lifetime and preventing a voltage rise and a decrease in efficiency after driven for a long time, a display and a lighting device both of which include the element. The organic electroluminescent element includes a luminescent layer sandwiched between an anode and a cathode, and a plurality of organic layers including the luminescent layer. The luminescent layer contains a phosphorescent compound and host compounds A and B both of which satisfy the following equations and requirement (11). Host Compound A=X+nR₁, Host Compound B=X+mR₂; and (11) [HOMO Energy level of Host Compound A]−[HOMO Energy level of Host Compound B]≥0.15 eV.

### FIELD OF INVENTION

The present invention relates to an organic electroluminescent element, a display and a lighting device both provided with the organic electroluminescent element.

### BACKGROUND ART

An organic electroluminescent element (hereinafter, also referred to as an “organic EL element”) is a thin film type of all-solid element formed of an organic thin layer (i.e., a single layer part or a multiple layers part) containing an organic luminescent substance, located between an anode and a cathode.

When a voltage is applied to an organic EL element, electrons are injected from a cathode to an organic thin layer, and holes are injected from an anode to the organic thin layer. The electrons and the holes are recombined in a luminescent layer (i.e., an organic luminescent substance-containing layer) to generate excitons. The organic EL element is a luminescent element using luminous radiation (i.e., fluorescence/phosphorescence) generated from those excitons, belonging to a technology expected as a next-generation of flat display and lighting. Here, the Princeton University reported that an organic EL element using phosphorescent emission from an excited triplet state, which principally enables realization of about 4-fold luminescent efficiency higher than a usual organic EL element using fluorescent emission. Since the report was published, research and development for electrodes and layer configurations of luminescent elements have been actively carried out over the world including development of a material exhibiting phosphorescence at room temperature.

As describe above, a method for emitting phosphorescence has greatly high potential, whereas a lifetime of the element cannot be said to be sufficiently long. Actually, the phosphorescent emission is applied to red emission and green emission in a smart phone and a television. However, conventional fluorescent emission is applied to blue emission, and an electronic display using the blue phosphorescence has not been realized yet.

In a luminescent element, a phosphorescent material is used as a mixed film with an organic compound usually called a host compound. This procedure mainly has two reasons. One is that a host compound plays a role in a dispersing agent of a luminescent material because agglomeration of the luminescent material decreases luminescent efficiency. The other is that a host compound plays a role in transporting charges (i.e., holes and electrons) to a luminescent material.

Here, there are three factors for influencing a lifetime of the element. The first one is that decomposition of the luminescent material makes the material nonluminescent. The second one is that a reaction caused by compounds other than a luminescent material decreases the excited triplet energy (T₁ energy) so as to generate a quencher, resulting in a decrease in luminescence. The third one is that change in charge mobility (i.e., holes and electrons) thus caused by change in film properties of the luminescent layer decreases a recombination probability in the luminescent layer and a lifetime caused by change in a recombination position.

Here, a blue phosphorescent material especially has a wide band gap, which lowers an energy level of HOMO and raises an energy level of LUMO, leading to a rise in the T₁ energy. This phenomenon decreases the energy gap of HOMOs between the blue phosphorescent material and the host compound, which makes the host compound mainly transport holes to increase the transporting rate of holes, so that a hole trapping ability of the luminescent material is decreased. It is construed that those effects decrease a recombination probability, shift a luminescent position to a cathode side, and decrease the luminescent area, causing a decrease in a lifetime of elements. Further, it is construed that the small energy gap of HOMOs between the blue phosphorescent material and the host compound facilitates generation of host excitons, changes film properties of the luminescent layer, thereby causing a decrease in carrier mobility and a recombination probability.

For addressing the above described issues, proposed is a method for obtaining a host compound having a large energy gap of HOMOs between the blue phosphorescent material and the host compound thus achieved by using an aromatic compound with a high accepter property as a host compound so as to decrease a HOMO energy level of the host compound. However, such a host compound with a high acceptor property has poor resistance of excitons, causing a defect of a short lifetime of element.

In view of the above, Patent Document 1 discloses a technology for improving a luminescent efficiency and drive voltage of a luminescent element by using two or more types of host compounds having 60% or more same structures in base skeletons of the host compounds and preventing crystallization of compounds used in a luminescent layer.

Further, Patent Document 2 discloses a technology for preventing agglomeration of host compounds to improve a lifetime of element and a drive voltage by limiting the total number of aromatic hydrocarbon cycles and aromatic heterocycles formed by condensation of 3˜5 rings, and the total number of aromatic hydrocarbon cycles and aromatic heterocycles formed by condensation of mono or bicycles, both in a host compound included in a luminescent layer.

However, those technologies are construed as a method for stabilizing film properties via suppressing agglomeration by mixing specific host compounds, while there is no description of controlling transport properties of carriers. Therefore, there is still room for improving disadvantages caused by specific properties of a blue phosphorescent material that a HOMO energy difference between a blue phosphorescent material and a host compound is small (for example, an disadvantage that a faster transport rate of holes decreases a recombination probability, a disadvantage that shift of a luminescent position to a cathode side decreases a luminescent area, a disadvantage that leakage of a carrier deteriorates a peripheral layer, and a disadvantage that easiness of generating host excitons causes change in film quality of a luminescent layer leading to a decrease in carrier mobility and a recombination probability). Thus, development of an organic electroluminescent element having an elongated lifetime and a suppressed voltage rise and a suppressed change in efficiency even after driven for a long time has been greatly demanded by means of controlling a transport ability of carriers and improving stability of film quality.

### DOCUMENTS OF PRIOR ART

### Patent Documents

Patent Document 1: WO2012/096236.
Patent Document 2: Japanese Unexamined Patent Application Publication No. 2014-179493.

### SUMMARY OF INVENTION

### Problems to be Solved by Invention

The present invention has been developed from the viewpoints of the above disadvantages and circumstances. Therefore, an object of the present invention is to provide an organic electroluminescent element having an elongated lifetime, a suppressed voltage rise and a suppressed decrease in efficiency even after driven for a long time, and a display and a lighting device both provided with the element.

### Means for Solving Problems

The present inventors reached the following findings while investigating causes of the above mentioned disadvantages in order to solve those disadvantages. Namely, one finding is use of two types of compounds. Herein, one is a predetermined compound and the other is a compound having a similar skeleton and a difference in a HOMO energy level of 0.15 eV or more prepared by substituting a hydrogen atom on the predetermined compound with an electron withdrawing group, or a 5- or 6-membered nitrogen-containing heterocycle in a luminescent layer of an organic EL element. The use of the two types of compounds enables change in the transport property of carrier as well as formation of a stably associated state of the two types of compounds to behave as one molecule due to the similar structures of the two compounds. The present inventors found out the object for providing such an organic EL element may be solved, as having higher film stability when energized, an elongated lifetime, and showing a suppressed voltage rise as well as a suppressed decrease in efficiency even after driven for a long time. Thereby, the present inventors have reached the present invention. That is, eventually the object of the present invention can be achieved by the following aspects.

1. An organic electroluminescent element including a luminescent layer sandwiched between an anode and a cathode, and a plurality of organic layers having the luminescent layer. Herein, the luminescent layer contains a phosphorescent compound, a host compound A and a host compound B both satisfying the following Equations and Requirement (11).

Host Compound A=X+nR₁

Host Compound B=X+mR₂

(In Equations, X represents a structure formed via linking a plurality of aromatic cyclic groups and having the same bonding position; the aromatic cyclic group means an aromatic hydrocarbon cyclic group or an aromatic heterocyclic group;

X of the host compound A and X of the host compound B have the same structure;

R₁ represents a hydrogen atom, a phenyl group that may have a substituent, or an alkyl group that may have a substituent;

R₂ represents an electron withdrawing group, a 5-membered nitrogen-containing heterocycle or a 6-membered nitrogen-containing heterocycle; and

“n” represents 0 or an integer of 1˜4, and when n is 0, R₁ represents a hydrogen atom; and “m” represents an integer of 1˜4)

[HOMO Energy Level of Host Compound A]−[HOMO Energy Level of Host Compound B]≥0.15 eV. (11)

2. An organic electroluminescent element described in the aspect 1, where the above described X is represented by the following General Formulae (2)˜(4).

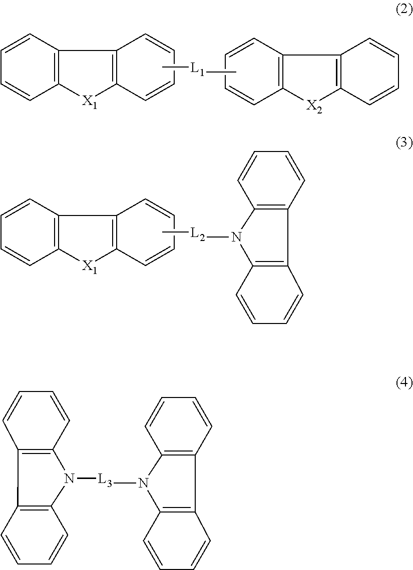

(In General Formulae (2)˜(4), X₁ and X₂ independently represent any one of an oxygen atom, a sulfur atom and a nitrogen atom, and when X₁ and/or X₂ is an nitrogen atom, X₁ and/or X₂ that is an nitrogen atom has a substituent; L₁, L₂ and L₃ represent a linker.)

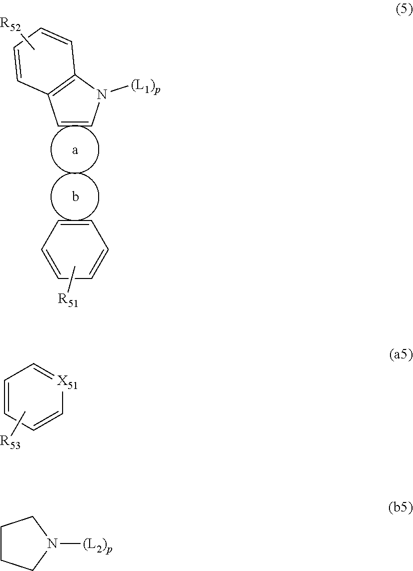

(In General Formula (5), “Ring a” represents an aromatic ring or a heterocyclic ring both represented by Formula (a5) fused to adjacent 2 rings at optional positions; X₅₁ represents C—R or a nitrogen atom; “Ring b” represents a heterocyclic ring represented by Formula (b5) fused to adjacent 2 rings at optional positions; L₁ and L₂ independently represent a C6˜22 (i.e., each numeral represents the number of carbon atoms forming the ring system and the definition is the same, hereinafter) aromatic hydrocarbon cyclic group, a C3˜16 aromatic heterocyclic group or a group thus formed via linking the 2˜10 groups; the aromatic hydrocarbon cyclic group and the aromatic heterocyclic group in L₁ and L₂ may have a substituent; “p” represents an integer of 0˜7; when “p” is 2 or more, L₁(s) may be the same or different respectively and L₂(s) may be the same or different respectively; R, and R₅₁˜R₅₃ independently represent a hydrogen atom, a C1˜20 alkyl group, a C7˜38 aralkyl group, a C2˜20 alkenyl group, C2˜20 alkynyl group, C2˜40 dialkylamino group a C12˜44 diarylamino group, a C14˜76 diaralkyl amino group, a C2˜20 acyl group, a C2˜20 acyloxy group, a C1˜20 alkoxy group, C2˜20 alkoxycarbonyloxy group, a C1˜20 alkylsulfonyl group, a C6˜22 aromatic hydrocarbon cyclic group or a C3˜16 aromatic heterocyclic group, and those groups may have a substituent respectively.)

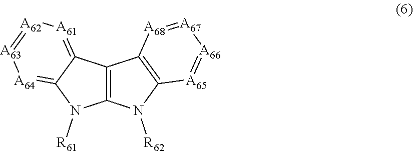

(In General Formula (6), A₆₁˜A₆₅ independently represent C—Rx or a nitrogen atom; a plurality of Rx(s) may be the same or different each other, the plurality Rx(s) independently represent a hydrogen atom or the same meaning as the substituent of General Formulae (2)˜(4); and R₆₁ and R₆₂ independently represent the same meaning as Rx.)

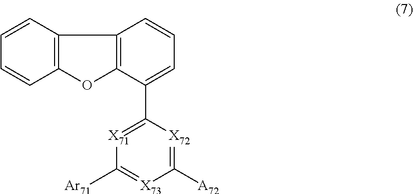

(In General Formula (7), X₇₁, X₇₂ and X₇₃ independently represent C—R′ or a nitrogen atom and at least one of X₇₁, X₇₂ and X₇₃ is a nitrogen atom; R′, Ar₇₁ and Ar₇₂ independently represent a hydrogen atom, a substituted or non-substituted C1˜12 alkyl group, or a substituted or non-substituted C6˜30 aryl group; and there is no case that all of R′, Ar₇₁ and Ar₇₂ are hydrogen atoms at the same time.)

3. An organic electroluminescent element described in any one of the aspects 1˜3, where R₂ is an electron withdrawing group, a 5-membered nitrogen-containing aromatic heterocyclic group or a 6-membered nitrogen-containing aromatic heterocyclic group.

4. An organic electroluminescent element described in any one of the aspects 1˜3, where the host compound A and the host compound B satisfy the following Requirements (12) and (13).

Exited Triplet Energies (i.e.,T₁ Energies) of Host Compound A and Host Compound B≥3.0 eV. (12)

[LUMO Energy Level of Host Compound A]−[LUMO Energy Level of Host Compound B]≥0.15 eV. (13)

5. An organic electroluminescent element described in any one of the aspects 1˜4, where the luminescent layer contains the phosphorescent compound satisfying the following Requirements (14)˜(16), the host compound A and the host compound B.

(14) A maximum wavelength of luminescence in a solution of the phosphorescent compound is 470 nm or less.

[HOMO Energy Level of Phosphorescent Compound]−[HOMO Energy Level of Host Compound B]≥0.35 eV. (15)

A ratio between the host compound A and the host compound B is 10:90˜90:10. (16)

6. A display provided with an organic electroluminescent element described in any one of the aspects 1˜5.

7. A lighting device provided with an organic electroluminescent element described in any one of the aspects 1˜5.

### Effect of Invention

According to the present invention, it is possible to provide an organic electroluminescent element having a long lifetime, a suppressed voltage rise and a suppressed decrease in efficiency even after driven for a long time, and a display and a lighting device both having the element.

### BRIEF DESCRIPTION OF DRAWINGS

FIG. 1 is a schematic diagram of a lighting device.

FIG. 2 is a cross-sectional diagram of the lighting device shown in FIG. 1.

FIG. 3 is an example of a display formed with an organic EL element.

FIG. 4 is a schematic diagram of the display unit A shown in FIG. 3.

FIG. 5 is a circuit diagram of pixels.

FIG. 6 is a schematic diagram of a display driven by a passive matrix method according to the display unit A in FIG. 3.

### EMBODIMENTS FOR CARRYING OUT INVENTION

Hereinafter, embodiments for carrying out the present invention will be described in detail. However, the present invention is not limited to those embodiments.

An organic electroluminescent element of the present invention can be preferably included in a display and a lighting device.

Hereinafter, the present invention, components thereof, and embodiments and aspects for carrying out the present invention will be described in detail. Herein, the mark of “˜” is used meaning that numerals described before and after the mark are included as a lower limit and an upper limit.

Note, according to the present invention, an energy level of HOMO (Highest Occupied Molecular Orbital) and an energy level of LUMO (Lowest Unoccupied Molecular Orbital) are values calculated by using a molecular orbital calculation software: Gaussian03 (Gaussian03, Revision D02, M. J. Frisch, et al., Gaussian Inc., Wallingford Conn., 2004).

HOMO energy levels and LUMO energy levels of the host compound A and the host compound B both used in the present invention are calculated by using B3LYP/6-31G* as a keyword, B3LYP/LanL2DZ for the phosphorescent compound and structurally optimizing a target molecular structure (i.e., an eV unit converted value). Here, the effectiveness of this calculation has a background reason that it is known that a calculated value obtained in this method highly correlates with an experimental value.

T₁ energies of the host compound A and the host compound B are calculated via the excited state calculation based on the time dependent density functional theory (Time-Dependent DFT).

<<Inducement Mechanism and Action Mechanism of Effects of Present Invention>>

An inducement mechanism and an action mechanism of effects of the present invention have not been clearly determined. However, the mechanisms are presumed as follows.

A blue phosphorescent material has a broad band gap, which increases a T₁ energy, lowers a HOMO energy level, and raises a LUMO energy level thereof. This phenomena decreases a HOMO energy gap between the blue phosphorescent material and the host compound, allowing a decrease in a hole trap ability of a dopant, faster mobility of holes since a host compound mainly performs the hole transport, a decrease in a recombination probability of carries, and a decrease in a luminescent area due to shift of a luminescent position to a cathode side. It is presumed that those phenomena cause a decrease in a lifetime of the element.

Further, it is also presumed that leakage of carriers to a peripheral layer causes a chemical change of the peripheral layer, which causes change in film quality of the peripheral layer and a decrease in a lifetime of element due to generation of quenchers. Moreover, it is presumed that tendency of a host compound converted to an exciton generates a chemical change in the host compound, causing a decrease in stability of film quality, a decrease in a T₁ energy, and a decrease in a lifetime of element caused by generation of quenchers.

As to the above described causes, use of two types of host compounds, which have a difference in the HOMO energy levels of 0.15 eV or more and form an associated body behaving as one molecule, may control the mobility property of carriers, suppress generation of host excitons, and further improve stability of film quality. Based on the above findings, the present inventors have found out solutions for achieving an elongated lifetime, a suppressed voltage rise and a suppressed decrease in efficiency of the element even after driven for a long time, and eventually reached the present invention.

<<Organic Electroluminescent Element>>

An organic EL element of the present invention includes a luminescent layer sandwiched between an anode and a cathode, and a plurality of organic layers containing the luminescent layer. Further, the luminescent layer contains a phosphorescent compound, and a host compound A and a host compound B both satisfying the following Equations and Requirement (11).

Hereinafter, organic EL materials of the present invention will be described specifically.

In the present invention, organic EL materials contained in the luminescent layer are a phosphorescent compound, a host compound A and a host compound B both satisfying the following Equations and Requirement (11).

Host Compound A=X+nR₁

Host Compound B=X+mR₂

In Equations, X represents a structure formed via linking a plurality of aromatic cyclic groups, and a structure having the same bonding positions. The aromatic cyclic group means an aromatic hydrocarbon cyclic group or an aromatic heterocyclic group.

Here, the term of a “structure having the same bonding positions” means that linkage sites (i.e., bonding positions) of a plurality of aromatic cyclic groups are the same in both X of the host compound A and X of the host compound B.

Further, X of the host compound A and X of the host compound B have the same structure.

The aromatic hydrocarbon cyclic group includes, for example, a benzene ring, a biphenyl group, a naphthalene ring, an azulene ring, an anthracene ring, a phenanthrene ring, a pyrene ring, a chrysene ring, a naphthacene ring, a triphenylene ring, an o-terphenyl ring, a m-terphenyl ring, a p-terphenyl ring, an acenaphthene ring, a coronene ring, a fluorene ring, a fluoranthrene ring, a naphthacene ring, a pentacene ring, a perylene ring, a pentaphene ring, a picene ring, a pyrene ring, a pyranthrene ring, and an anthranthrene ring or the like. The most preferable one is a benzene ring.

The aromatic heterocyclic group includes, for example, a silole ring, a furan ring, a thiophene ring, an oxazole ring, a pyrrole ring, a pyridine ring, a pyridazine ring, a pyrimidine ring, a pyrazine ring, a triazine ring, an oxadiazole ring, a triazole ring, an imidazole ring, a pyrazole ring, a thiazole ring, an indole ring, a benzimidazole ring, a benzthiazole ring, a benzoxazole ring, a quinoxaline ring, a quinazoline ring, a phthalazine ring, a thienothiophene ring, a carbazole ring, an azacarbazole ring (i.e., a ring in which at least optional one carbon atom forming a carbazole ring is replaced by a nitrogen atom), a dibenzosilole ring, a dibenzofuran ring, a dibenzothiophene ring, a ring in which at least one carbon atom forming a benzothiophene ring or a dibenzofuran ring is replaced by a nitrogen atom, a benzodifuran ring, a benzodithiophene ring, an acridine ring, a benzoquinoline ring, a phenazine ring, a phenanthridine ring, a phenanthroline ring, a cyclazine ring, a quindoline ring, a tepenidine ring, a quinindoline ring, a triphenodithiazine ring, a triphenodioxazine ring, a phenanthrazine ring, an anthrazine ring, a perimidine ring, a naphthofuran ring, a naphthothiophene ring, a naphthodifuran ring, a naphthodithiophene ring, an anthrafuran ring, an anthradifuran ring, an anthrathiophene ring, an anthradithiophene ring, a thianthrene ring, a phenoxathiin ring, a dibenzocarbazole ring, an indolocarbazole ring, and a dithienobenzene ring or the like. The most preferable rings are a dibenzofuran ring and a carbazole ring.

Here, the above aromatic hydrocarbon cyclic groups and aromatic heterocyclic groups may have a substituent.

R₁ represents a hydrogen atom, a phenyl group that may have a substituent, or an alkyl group that may have a substituent.

Such a phenyl group includes, for example, a phenyl group, a p-chlorophenyl group, a mesityl group, a tolyl group, a xylyl group, a naphthyl group, an anthryl group, an azulenyl group, an acenaphthenyl group, a fluorenyl group, a phnenthryl group, an indenyl group, a pyrenyl group, and a biphenyl group or the like.

Such an alkyl group includes, for example, a methyl group, an ethyl group, a n-propyl group, an isopropyl group, an n-butyl group, a sec-butyl group, a t-butyl group, a pentyl group, a hexyl group, an octyl group, a dodecyl group, a tridecyl group, a tetradecyl group, and a pentadecyl group or the like.

R₂ represents an electron withdrawing group, a 5-membered nitrogen-containing heterocyclic group or a 6-membered nitrogen-containing heterocyclic group.

As to the electron withdrawing group, at least one group may be used that is selected from a cyano group, a nitro group, an alkylphosphino group, an arylphosphino group, an acyl group, a fluoroalkyl group, a pentafluorosulfanyl group, and a halogen atom. The alkylphosphino group includes, for example, a dimethylphosphino group, a dimethylphosphino group, and a dicyclohexylphosphino group or the like. Further, the arylphosphino group includes, for example, a diphenylphosphino group and a dinaphthylphosphino group or the like. The acyl group includes, for example, an acetyl group, an ethylcarbonyl group, and a propylcarbonyl group, or the like. Moreover, a fluoroalkyl group includes, for example, a trifluoromethyl group and a pentafluoroethyl group or the like. Furthermore, the halogen atom includes, for example, a fluorine atom, a bromine atom or the like. Here, a preferable electron withdrawing group is a cyano group.

The 5- or 6-membered nitrogen containing heterocyclic group may have a substituent or no substituent. Further, those nitrogen-containing heterocyclic groups may be a monocyclic group or form a polycyclic fused ring via further condensation of a 5-membered ring or a 6-membered ring.

The 5-membered nitrogen-containing heterocyclic group is, for example, a 5-membered nitrogen-containing aromatic heterocyclic group, and the 6-membered nitrogen-containing heterocyclic group is, for example, a 6-membered nitrogen-containing aromatic heterocyclic group.

Specifically, such a 5-membered nitrogen-containing aromatic heterocyclic group includes a pyrrole ring, a pyrazole ring, an imidazole ring, a triazole ring, an oxazole ring, an oxadiazole ring, and a thiazole ring or the like. Further, specifically such a 6-membered nitrogen-containing aromatic heterocyclic group includes a pyridine ring, a pyridazine ring, a pyrazine ring and a triazine ring or the like.

Note, as for R₂, other multi-membered nitrogen-containing aromatic heterocycles may be used, including an indole ring, a benzimidazole ring, a benzoxazole ring, a benzthiazole ring, a quinoline ring, a quinazoline ring, a quinoxaline ring, a phthalazine ring, a carbazole ring, an azacarbazole ring (i.e., a ring in which at least one carbon atom forming a carbazole ring is replaced by a nitrogen atom), a dibenzocarbazole ring, an indolocarbazole ring, an acridine ring, a phenazine ring, a benzoquinoline ring, a phenanthridine ring, a phenanthroline ring, a cyclazine ring, a quindoline ring, a tepenidine ring, a quinindoline ring, a triphenodioxazine ring, a phenanthrazine ring, an anthrazine ring, and a perimidine ring or the like.

“n” represents 0 or an integer of 1˜4, and when “n” is 0, R₁ represents a hydrogen atom. “m” represents an integer of 1˜4.

(Requirement (11))

[HOMO Energy Level of Host Compound A]−[HOMO Energy Level of Host Compound B]≥0.15 eV. (11)

When a value of the equation in Requirement (11) is less than 0.15 eV, holes are transported by the host compounds A and B. This phenomenon increases mobility of holes, decreases a lifetime of the element due to a decrease in a recombination probability and a luminescent area, thereby to cause a voltage rise and deterioration of efficiency after driven for a long time. Therefore, the value of the equation in Requirement (11) is set to 0.15 eV or more. From the viewpoints of elongating a lifetime of the element and suppressing a voltage rise and a decrease in efficiency after driven for a long time, preferably the value is set to 0.17 eV, more preferably 0.20 eV. Herein, the upper limit is not specifically defined. However, from the viewpoint of carrier transportability, preferably the value is set to 0.60 eV or less.

X(s) of the host compounds A and B include, for example, structures represented by the following General Formulae (2)˜(7). However, X(s) are not limited to those structures.

<Compounds Represented by General Formulae (2)˜(4)>

Next, General Formulae (2)˜(4) will be described more specifically.

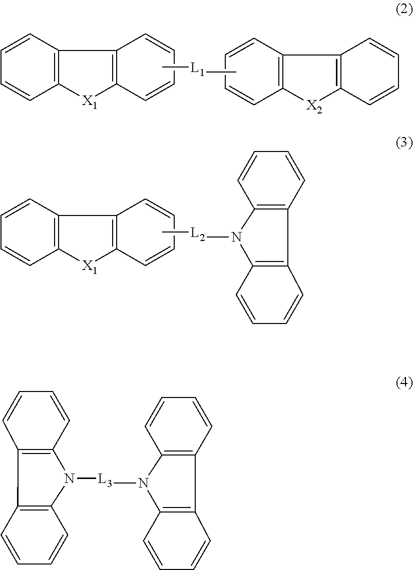

In General Formulae (2)˜(4), X₁ and X₂ independently represent any one of an oxygen atom, a sulfur atom and a nitrogen atom, and when X₁ or X₂ is a nitrogen atom, X₁ or X₂ of a nitrogen atom has a substituent.

As for such a substituent, useable are, for example, an alkyl group, a cycloalkyl group, an alkenyl group, an alkynyl group, an aromatic hydrocarbon cyclic group (i.e., also referred to as an aryl group, for example, a phenyl group, a p-chlorophenyl group, a mesityl group, a tolyl group, a xylyl group, a naphthyl group, an anthryl group, an azulenyl group, an acenaphthenyl group, a fluorenyl group, a phnenthryl group, an indenyl group, a pyrenyl group, and a biphenyl group or the like), a non-aromatic heterocyclic group, an aromatic heterocyclic group (i.e., also referred to as a heteroaryl group, including a pyridyl group, a pyrimidyl group, a furyl group, a pyrrolyl group, an imidazolyl group, a benzoimidazolyl group, a pyrazolyl group, a pyrazinyl group, a triazolyl group, an oxazolyl group, a bonzoxazolyl group, a thiazolyl group, an isoxazolyl group, an isothiazolyl group, a furazanyl group, a thienyl group, a quinolyl group, a benzofuryl group, a dibenzofuranyl group, a dibenzothienyl group, a dibenzothiophenyl group, an indolyl group, a carbazolyl group, a carbolinyl group, a diazacarbazolyl group, a quinoxalinyl group, a pyridazinyl group, a triazinyl group, a quinazolinyl group, and a phthalazinyl group or the like), a halogen atom, an alkoxyl group, a cycloalkoxyl group, an aryloxy group, an alkoxycarbonyl group, an aryloxycarbonyl group, an acyl group, an acyloxy group, an amide group, an arylsulfonyl group, an amino group, a diarylamino group, an arylsilyl group, an arylphosphino group, and an arylphosphoryl group.

Note, those groups may be further substituted by the above described substituent, and those groups may be fused each other to further form a ring system.

The substituent is preferably an aryl group or a heteroaryl group. A preferable aryl group is a phenyl group. A preferable heteroaryl group includes a dibenzofuranyl group, a dibenzothiophenyl group and a carbazolyl group. In the aryl group and the heteroaryl group, a part of carbon atoms forming each aromatic ring may be replaced by a nitrogen atom. Further, the aryl group and the heteroaryl group may have a substituent.

In General Formulae (2)˜(4), L₁, L₂ and L₃ represent a linker.

A linker represented by L₁, L₂ and L₃ may be, for example, a hydrocarbon group including an alkylene group, an alkenylene group, an alkynylene group, and an arylene group. Further, besides those groups, the linker may be a group including a hetero atom, and a linker derived from an aromatic group, a heterocyclic group. More specifically, the aromatic group includes a ring system of benzene, toluene and naphthalene. The heterocyclic group includes a ring system of, specifically, pyridine, thiazole, imidazole, furan, thiophene, pyrimidine, dibenzofuran and carbazole

<Compound Represented by General Formula (5)>

Next, General Formula (5) will be described specifically.

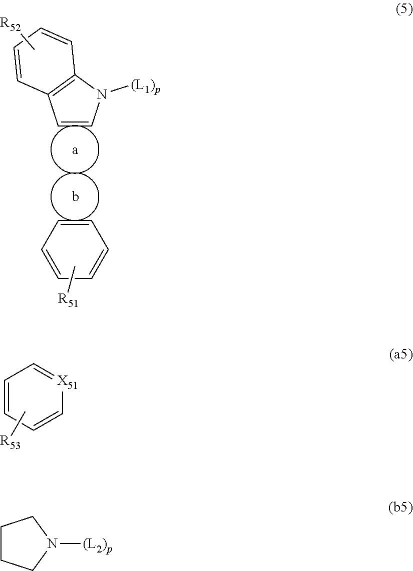

(In General Formula (5), “Ring a” represents an aromatic cycle or a heterocycle represented by Formula (a5) fused to adjacent 2 rings at optional positions; X₅₁ represents C—R or a nitrogen atom; “Ring b” represents a heterocyclic ring represented by Formula (b5) fused to adjacent 2 rings at optional positions; L₁ and L₂ independently represent a C6˜22 aromatic hydrocarbon cyclic group, a C3˜16 aromatic heterocyclic group or a group thus formed via linking those 2˜10 groups. Those aromatic hydrocarbon cyclic groups and aromatic heterocyclic groups in L₁ and L₂ may have a substituent; “p” represents an integer of 0˜7. Here, when “p” is 2 or more, L₁(s) may be the same or different respectively and L₂(s) may be the same or different respectively. R, R₅₁˜R₅₃ independently represent a hydrogen atom, a C1˜20 alkyl group, a C7˜38 aralkyl group, a C2˜20 alkenyl group, a C2˜20 alkynyl group, a C2˜40 dialkylamino group, a C12˜44 diarylamino group, a C14˜76 diaralkylamino group, a C2˜20 acyl group, a C2˜20 acyloxy group, a C1˜20 alkoxy group, a C2˜20 alkoxycarbonyl group, a C2˜20 alkoxycarbonyloxy group, a C1˜20 alkylsulfonyl group, a C6˜22 aromatic hydrocarbon cyclic group, or a C3˜16 aromatic heterocyclic group. Further, those groups may have a substituent, respectively.

In General Formula (5), X₅₁ in Formula (a5) is preferably C—R.

<Compound Represented by General Formula (6)>

Next, General Formula (6) will be described more specifically.

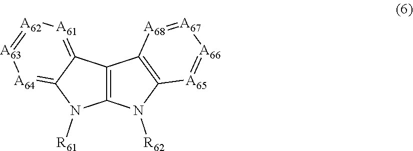

In General Formula (6), A₆₁˜A₆₈ independently represent C—Rx or a nitrogen atom (N), and a plurality of Rx(s) may be the same or different respectively. When one or more of A₆₁˜A₆₈ is N, a charge transport ability is improved, and a voltage rise when driven at a low voltage may be suppressed at a low level.

Further, preferably at least one of A₆₁ and A₆₃ is N, and more preferably A₆₁ is N in a preferable aspect. On the other hand, when all of A₆₁˜A₆₈ are C—Rx, such a case represents a preferable aspect because the case can more improve durability. In General Formula (6), especially each of A₆₁˜A₆₈ is preferably C—Rx.

The plurality of Rx(s) independently represent a hydrogen atom or the same meaning as the substituents in General Formulae (2)˜(4), and include the same structures as the substituents. Note, those substituents may be further substituted by the substituents described in General Formulae (2)˜(4), or may be fused each other to form another ring system. When Rx is a substituent, Rx is preferably an arylphosphoryl group, an aromatic hydrocarbon cyclic group or an aromatic heterocyclic group.

In General Formula (6), R₆₁ and R₆₂ independently represent the same meaning as Rx. R₆₁ and R₆₂ are preferably any one of an arylsilyl group, an arylphosphoryl group, an aromatic hydrocarbon cyclic group, an aromatic heterocyclic group, a diarylamino group, and more preferably either of an aromatic hydrocarbon cyclic group or an aromatic heterocyclic group. A preferably aromatic hydrocarbon cyclic group includes a phenyl group, and a preferable aromatic heterocyclic group includes a dibenzofuryl group or the like.

<Compound Represented by General Formula (7)>

Next, a compound represented by General Formula (7) will be described more specifically.

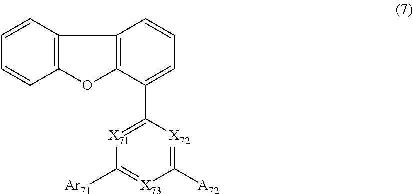

In General Formula (7), X₇₁, X₇₂ and X₇₃ independently represent C—R′ or a nitrogen atom, and at least one of X₇₁, X₇₂ and X₇₃ is a nitrogen atom.

Preferably, two or three of X₇₁, X₇₂ and X₇₃ represent a nitrogen atom, and more preferably all of X₇₁, X₇₂ and X₇₃ represent a nitrogen atom.

In General Formula (7), R′, Ar₇₁ and Ar₇₂ independently represent a hydrogen atom, a substituted or non-substituted C1˜12 alkyl group, or a substituted or non-substituted C6˜30 aryl group. Here, there is no case that all of R′, Ar₇₁ and Ar₇₂ simultaneously represent a hydrogen atom.

Preferably, R′ is a hydrogen atom or an alkyl group, more preferably a hydrogen atom. Preferably, Ar₇₁ and Ar₇₂ represent a C1˜12 alkyl group or a C6˜30 aryl group, and more preferably Ar₇₁ and Ar₇₂ represent a C4 or less (i.e., the number of carbon atoms is 4 or less) alkyl group or a C6˜12 (i.e., the number of carbon atoms forming the ring system is 6˜12) aryl group.

Hereinafter, examples of the host compounds A and B will be described. However, the present invention is not limited to those examples.

TABLE 1

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 201a | 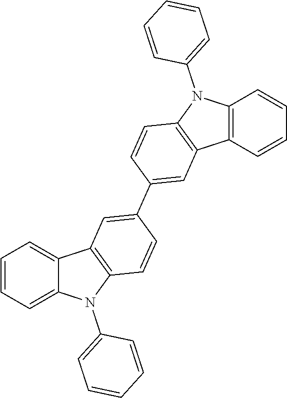 [SMILES: c1ccc(-n2c3ccccc3c3cc(-c4ccc5c(c4)c4ccccc4n5-c4ccccc4)ccc32)cc1] | 3.03 | −4.97 | −0.67 |
| 202a | 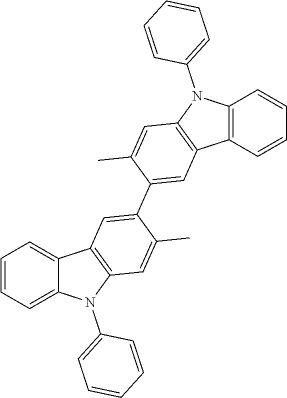 [SMILES: Cc1cc2c(cc1-c1cc3c4ccccc4n(-c4ccccc4)c3cc1C)c1ccccc1n2-c1ccccc1] | 3.14 | −5.24 | −0.62 |
| 203a | 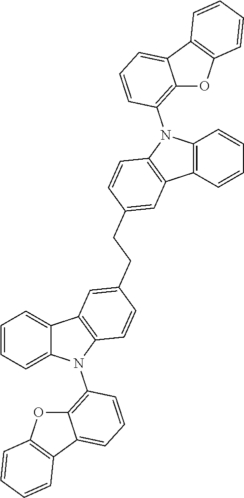 [SMILES: c1ccc2c(c1)oc1c(-n3c4ccccc4c4cc(CCc5ccc6c(c5)c5ccccc5n6-c5cccc6c5oc5ccccc56)ccc43)cccc12] | 3.09 | −5.17 | −1.15 |
| 204a | 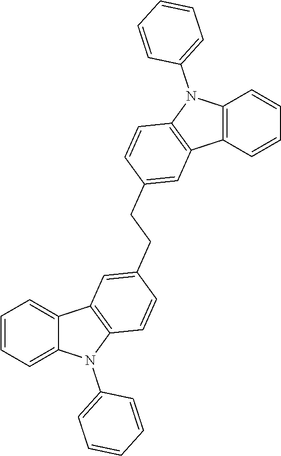 [SMILES: c1ccc(-n2c3ccccc3c3cc(CCc4ccc5c(c4)c4ccccc4n5-c4ccccc4)ccc32)cc1] | 3.16 | −5.18 | −.063 |

Host Compound B

| | | | | |
|---|---|---|---|---|
| 251b | 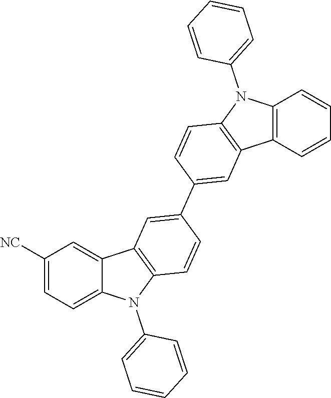 [SMILES: N#Cc1ccc2c(c1)c1cc(-c3ccc4c(c3)c3ccccc3n4-c3ccccc3)ccc1n2-c1ccccc1] | 3.00 | −5.21 | −1.12 |
| 252b | 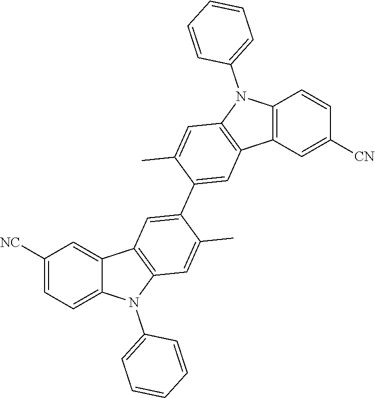 [SMILES: Cc1cc2c(cc1-c1cc3c4cc(C#N)ccc4n(-c4ccccc4)c3cc1C)c1cc(C#N)ccc1n2-c1ccccc1] | 3.10 | −5.80 | −1.20 |
| 253b | 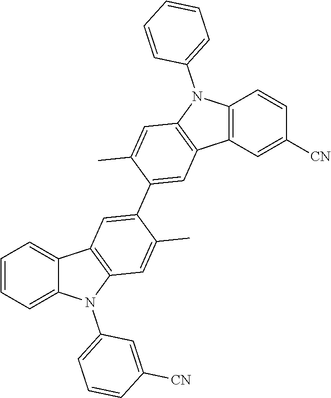 [SMILES: Cc1cc2c(cc1-c1cc3c4cc(C#N)ccc4n(-c4ccccc4)c3cc1C)c1ccccc1n2-c1cccc(C#N)c1] | 3.08 | −5.67 | −1.67 |
| 254b | 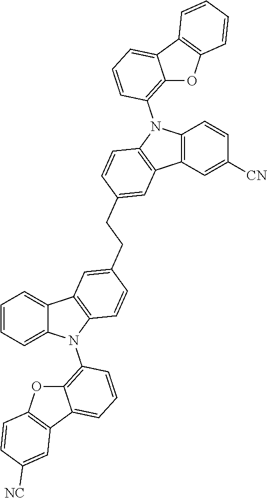 [SMILES: N#Cc1ccc2oc3c(-n4c5ccccc5c5cc(CCc6ccc7c(c6)c6cc(C#N)ccc6n7-c6cccc7c6oc6ccccc67)ccc54)cccc3c2c1] | 3.00 | −5.50 | −1.68 |
| 255b | 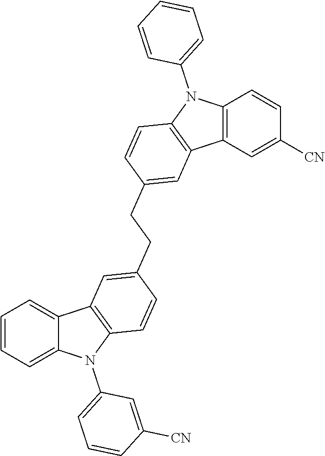 [SMILES: N#Cc1cccc(-n2c3ccccc3c3cc(CCc4ccc5c(c4)c4cc(C#N)ccc4n5-c4ccccc4)ccc32)c1] | 3.06 | −5.59 | −1.67 |
| 256b | 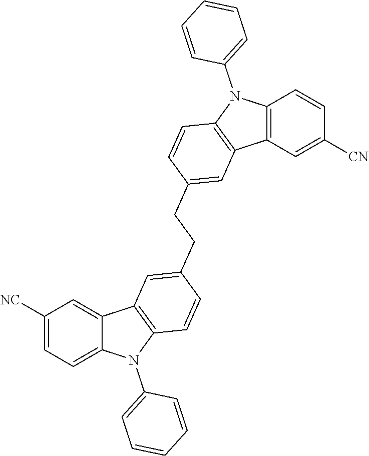 [SMILES: N#Cc1ccc2c(c1)c1cc(CCc3ccc4c(c3)c3cc(C#N)ccc3n4-c3ccccc3)ccc1n2-c1ccccc1] | 3.10 | −5.70 | −1.19 |

TABLE 2

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 205a | 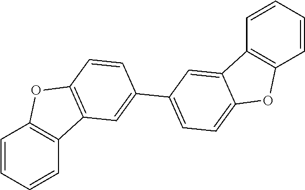 [SMILES: c1ccc2c(c1)oc1ccc(-c3ccc4oc5ccccc5c4c3)cc12] | 3.10 | −5.71 | −1.00 |
| 206a | 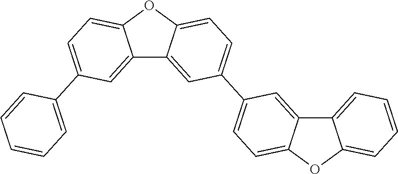 [SMILES: c1ccc(-c2ccc3oc4ccc(-c5ccc6oc7ccccc7c6c5)cc4c3c2)cc1] | 3.08 | −5.70 | −1.04 |

Host Compound B

| | | | | |
|---|---|---|---|---|
| 257b | 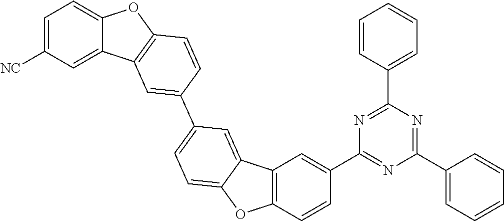 [SMILES: N#Cc1ccc2oc3ccc(-c4ccc5oc6ccc(-c7nc(-c8ccccc8)nc(-c8ccccc8)n7)cc6c5c4)cc3c2c1] | 2.97 | −6.07 | −1.90 |
| 258b | 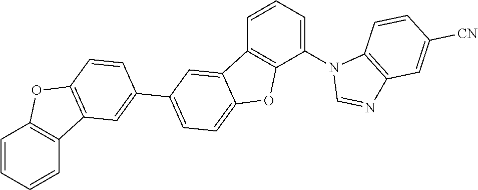 [SMILES: N#Cc1ccc2c(c1)ncn2-c1cccc2c1oc1ccc(-c3ccc4oc5ccccc5c4c3)cc12] | 3.09 | −6.03 | −1.62 |
| 259b | 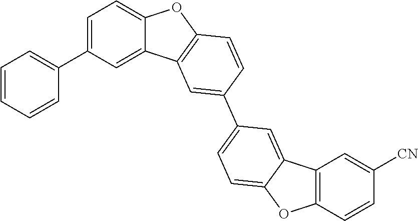 [SMILES: N#Cc1ccc2oc3ccc(-c4ccc5oc6ccc(-c7ccccc7)cc6c5c4)cc3c2c1] | 3.07 | −5.91 | −1.50 |
| 260b | 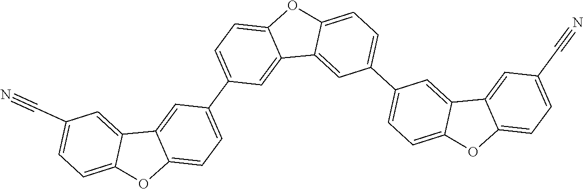 [SMILES: N#Cc1ccc2oc3ccc(-c4ccc5oc6ccc(-c7ccc8oc9ccc(C#N)cc9c8c7)cc6c5c4)cc3c2c1] | 3.06 | −6.06 | −1.57 |

TABLE 3

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 301a | 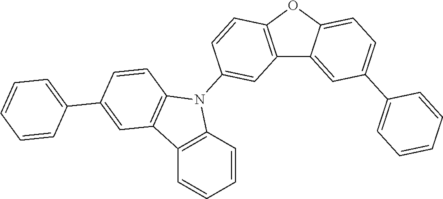 [SMILES: c1ccc(-c2ccc3oc4ccc(-n5c6ccccc6c6cc(-c7ccccc7)ccc65)cc4c3c2)cc1] | 3.08 | −5.23 | −1.26 |
| 302a | 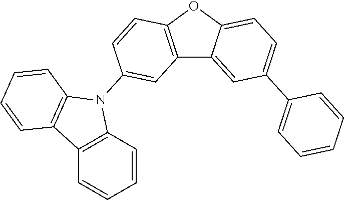 [SMILES: c1ccc(-c2ccc3oc4ccc(-n5c6ccccc6c6ccccc65)cc4c3c2)cc1] | 3.11 | −5.32 | −1.24 |
| 303a | 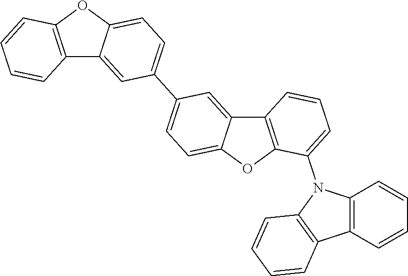 [SMILES: c1ccc2c(c1)oc1ccc(-c3ccc4oc5c(-n6c7ccccc7c7ccccc76)cccc5c4c3)cc12] | 3.06 | −5.35 | −1.23 |
| 304a | 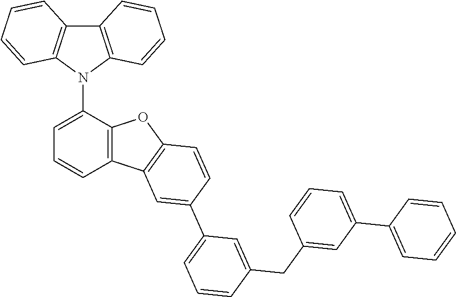 [SMILES: c1ccc(-c2cccc(Cc3cccc(-c4ccc5oc6c(-n7c8ccccc8c8ccccc87)cccc6c5c4)c3)c2)cc1] | 3.07 | −5.34 | −1.21 |
| 305a | 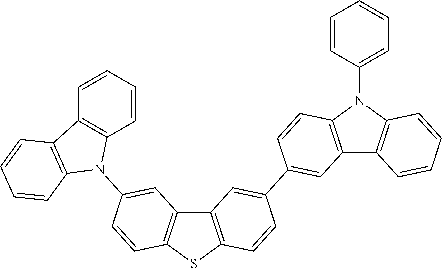 [SMILES: c1ccc(-n2c3ccccc3c3cc(-c4ccc5sc6ccc(-n7c8ccccc8c8ccccc87)cc6c5c4)ccc32)cc1] | 3.00 | −5.24 | −1.15 |

Host Compound B

| | | | | |
|---|---|---|---|---|
| 351b | 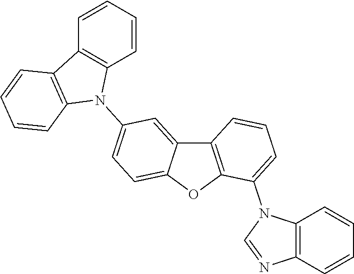 [SMILES: c1ccc2c(c1)ncn2-c1cccc2c1oc1ccc(-n3c4ccccc4c4ccccc43)cc12] | 3.10 | −5.46 | −1.55 |
| 352b | 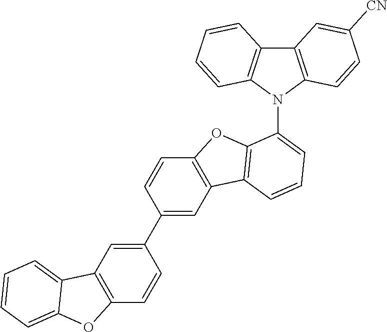 [SMILES: N#Cc1ccc2c(c1)c1ccccc1n2-c1cccc2c1oc1ccc(-c3ccc4oc5ccccc5c4c3)cc12] | 3.07 | −5.79 | −1.47 |
| 353b | 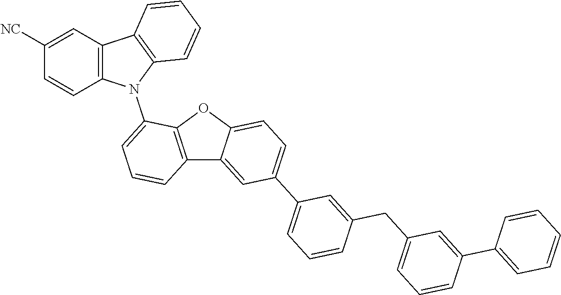 [SMILES: N#Cc1ccc2c(c1)c1ccccc1n2-c1cccc2c1oc1ccc(-c3cccc(Cc4cccc(-c5ccccc5)c4)c3)cc12] | 3.08 | −5.79 | −1.46 |
| 354b | 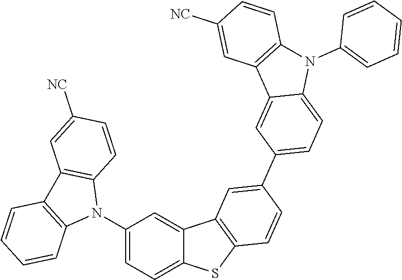 [SMILES: N#Cc1ccc2c(c1)c1ccccc1n2-c1ccc2sc3ccc(-c4ccc5c(c4)c4cc(C#N)ccc4n5-c4ccccc4)cc3c2c1] | 3.00 | −5.74 | −1.51 |

TABLE 4

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 401a | 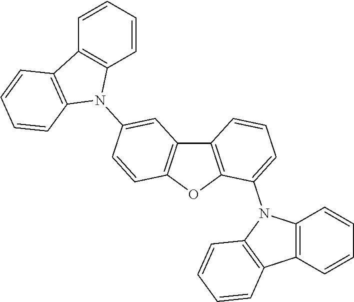 [SMILES: c1cc(-n2c3ccccc3c3ccccc32)c2oc3ccc(-n4c5ccccc5c5ccccc54)cc3c2c1] | 3.05 | −5.38 | −1.42 |
| 402a | 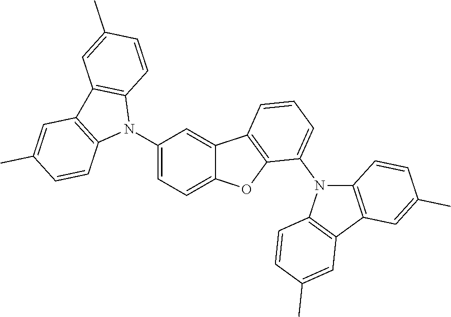 | 3.00 | −5.19 | −1.35 |
| 403a | 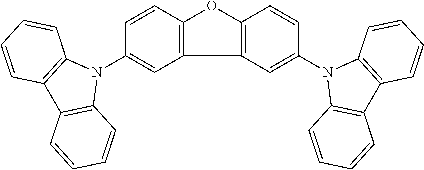 [SMILES: c1ccc2c(c1)c1ccccc1n2-c1ccc2oc3ccc(-n4c5ccccc5c5ccccc54)cc3c2c1] | 3.13 | −5.38 | −1.44 |
| 404a | 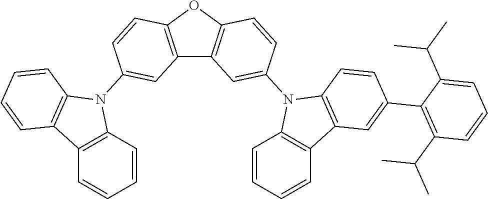 [SMILES: CC(C)c1cccc(C(C)C)c1-c1ccc2c(c1)c1ccccc1n2-c1ccc2oc3ccc(-n4c5ccccc5c5ccccc54)cc3c2c1] | 3.12 | −5.40 | −1.48 |
| 405a | 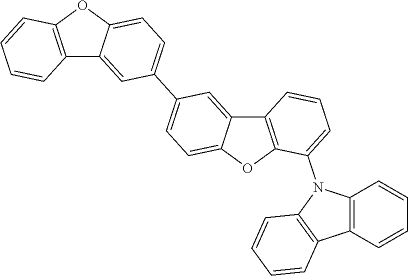 [SMILES: c1ccc2c(c1)oc1ccc(-c3ccc4oc5c(-n6c7ccccc7c7ccccc76)cccc5c4c3)cc12] | 3.06 | −5.35 | −1.32 |

Host Compound B

| | | | | |
|---|---|---|---|---|
| 451b | 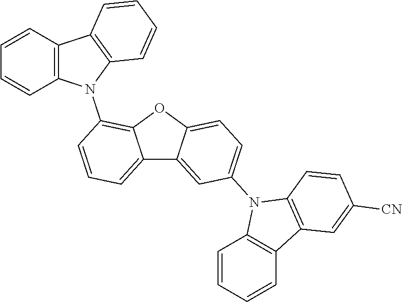 [SMILES: N#Cc1ccc2c(c1)c1ccccc1n2-c1ccc2oc3c(-n4c5ccccc5c5ccccc54)cccc3c2c1] | 3.03 | −5.55 | −1.64 |
| 452b | 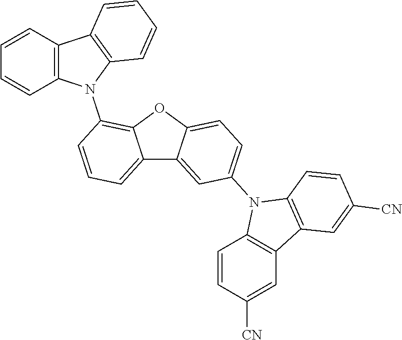 [SMILES: N#Cc1ccc2c(c1)c1cc(C#N)ccc1n2-c1ccc2oc3c(-n4c5ccccc5c5ccccc54)cccc3c2c1] | 2.99 | −5.65 | −1.85 |
| 453b | 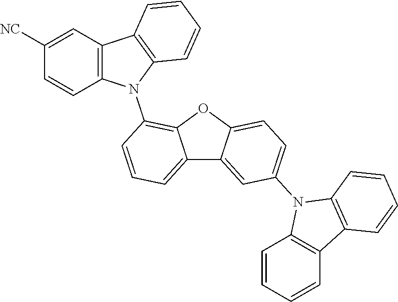 [SMILES: N#Cc1ccc2c(c1)c1ccccc1n2-c1cccc2c1oc1ccc(-n3c4ccccc4c4ccccc43)cc12] | 3.07 | −5.51 | −1.66 |
| 454b | 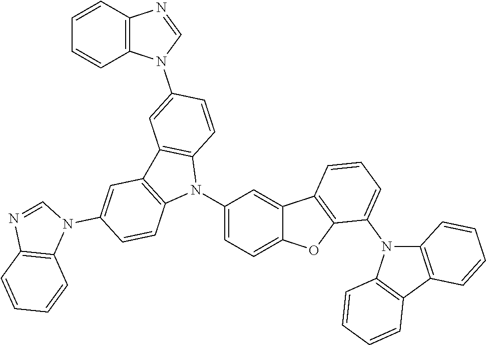 [SMILES: c1ccc2c(c1)ncn2-c1ccc2c(c1)c1cc(-n3cnc4ccccc43)ccc1n2-c1ccc2oc3c(-n4c5ccccc5c5ccccc54)cccc3c2c1] | 3.01 | −5.58 | −1.71 |
| 456b | 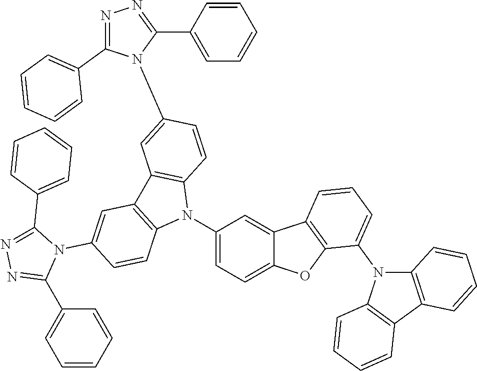 [SMILES: c1ccc(-c2nnc(-c3ccccc3)n2-c2ccc3c(c2)c2cc(-n4c(-c5ccccc5)nnc4-c4ccccc4)ccc2n3-c2ccc3oc4c(-n5c6ccccc6c6ccccc65)cccc4c3c2)cc1] | 3.00 | −5.64 | −1.81 |
| 457b | 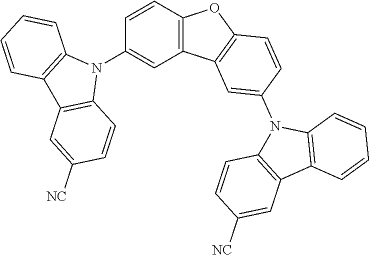 [SMILES: N#Cc1ccc2c(c1)c1ccccc1n2-c1ccc2oc3ccc(-n4c5ccccc5c5cc(C#N)ccc54)cc3c2c1] | 3.12 | −5.94 | −1.89 |
| 458b | 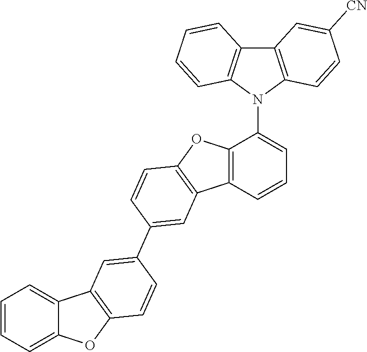 [SMILES: N#Cc1ccc2c(c1)c1ccccc1n2-c1cccc2c1oc1ccc(-c3ccc4oc5ccccc5c4c3)cc12] | 3.07 | −5.79 | −1.47 |

TABLE 5

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 501a | 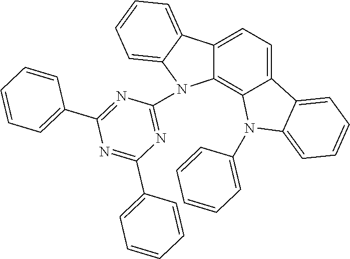 [SMILES: c1ccc(-c2nc(-c3ccccc3)nc(-n3c4ccccc4c4ccc5c6ccccc6n(-c6ccccc6)c5c43)n2)cc1] | 2.78 | −5.26 | −1.87 |
| 502a | 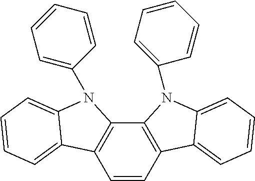 [SMILES: c1ccc(-n2c3ccccc3c3ccc4c5ccccc5n(-c5ccccc5)c4c32)cc1] | 2.92 | −5.10 | −0.85 |

Host Compound B

| | | | | |
|---|---|---|---|---|
| 551b | 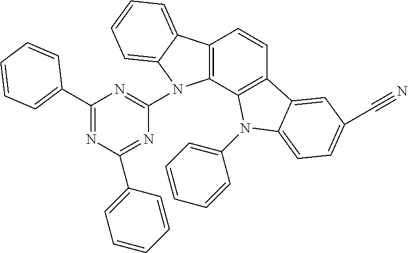 [SMILES: N#Cc1ccc2c(c1)c1ccc3c4ccccc4n(-c4nc(-c5ccccc5)nc(-c5ccccc5)n4)c3c1n2-c1ccccc1] | 2.84 | −5.62 | −2.07 |
| 552b | 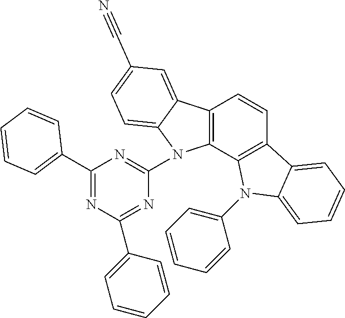 [SMILES: N#Cc1ccc2c(c1)c1ccc3c4ccccc4n(-c4ccccc4)c3c1n2-c1nc(-c2ccccc2)nc(-c2ccccc2)n1] | 2.82 | −5.53 | −2.12 |
| 553b | 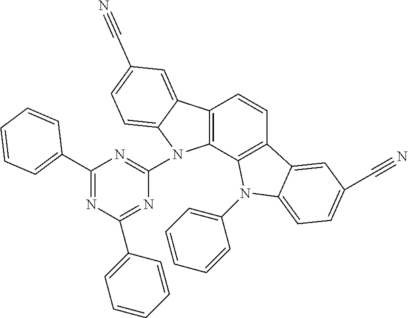 [SMILES: N#Cc1ccc2c(c1)c1ccc3c4cc(C#N)ccc4n(-c4nc(-c5ccccc5)nc(-c5ccccc5)n4)c3c1n2-c1ccccc1] | 2.86 | −5.89 | −2.30 |
| 554b | 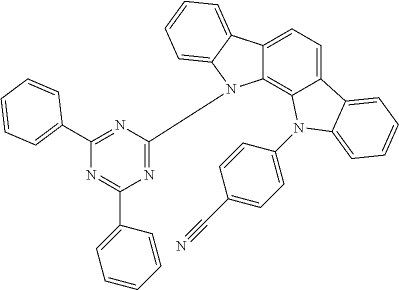 [SMILES: N#Cc1ccc(-n2c3ccccc3c3ccc4c5ccccc5n(-c5nc(-c6ccccc6)nc(-c6ccccc6)n5)c4c32)cc1] | 2.81 | −5.55 | −2.03 |
| 555b | 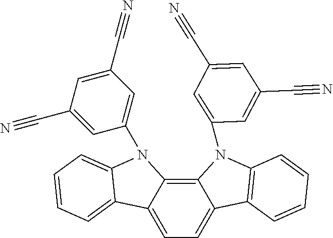 [SMILES: N#Cc1cc(C#N)cc(-n2c3ccccc3c3ccc4c5ccccc5n(-c5cc(C#N)cc(C#N)c5)c4c32)c1] | 2.78 | −6.03 | −2.55 |

TABLE 6

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 601a | 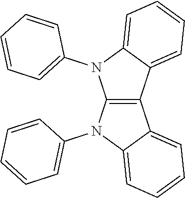 [SMILES: c1ccc(-n2c3ccccc3c3c4ccccc4n(-c4ccccc4)c32)cc1] | 3.15 | −4.78 | −0.56 |
| 602a | 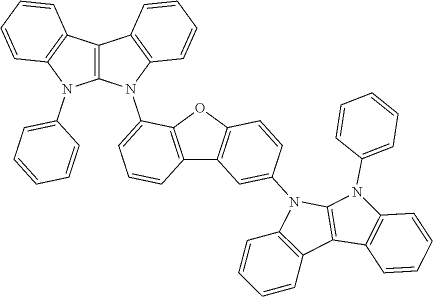 [SMILES: c1ccc(-n2c3ccccc3c3c4ccccc4n(-c4ccc5oc6c(-n7c8ccccc8c8c9ccccc9n(-c9ccccc9)c87)cccc6c5c4)c32)cc1] | 2.79 | −4.78 | −1.51 |

Host Compound B

| | | | | |
|---|---|---|---|---|
| 651b | 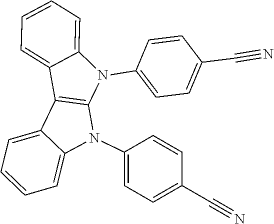 [SMILES: N#Cc1ccc(-n2c3ccccc3c3c4ccccc4n(-c4ccc(C#N)cc4)c32)cc1] | 3.39 | −6.55 | −1.02 |
| 652b | 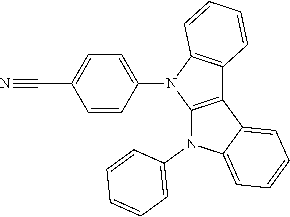 [SMILES: N#Cc1ccc(-n2c3ccccc3c3c4ccccc4n(-c4ccccc4)c32)cc1] | 2.68 | −5.07 | −1.66 |
| 653b | 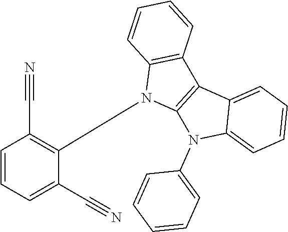 [SMILES: N#Cc1cccc(C#N)c1-n1c2ccccc2c2c3ccccc3n(-c3ccccc3)c21] | 2.13 | −4.99 | −2.29 |
| 654b | 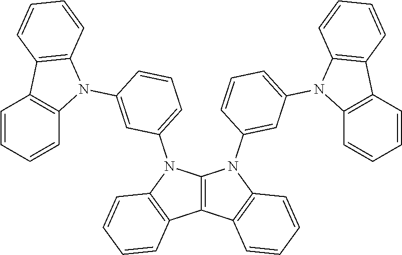 [SMILES: c1cc(-n2c3ccccc3c3ccccc32)cc(-n2c3ccccc3c3c4ccccc4n(-c4cccc(-n5c6ccccc6c6ccccc65)c4)c32)c1] | 3.08 | −4.97 | −1.00 |
| 655b | 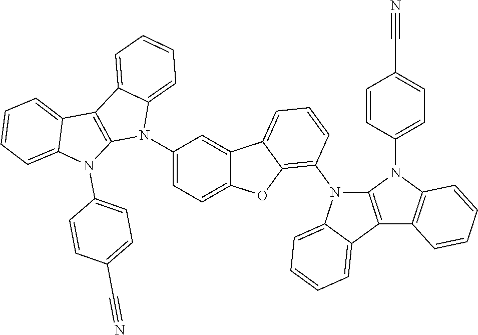 [SMILES: N#Cc1ccc(-n2c3ccccc3c3c4ccccc4n(-c4ccc5oc6c(-n7c8ccccc8c8c9ccccc9n(-c9ccc(C#N)cc9)c87)cccc6c5c4)c32)cc1] | 2.60 | −5.08 | −1.86 |

TABLE 7

| | | | | |
|---|---|---|---|---|
| | | T₁ | HOMO | LUMO |
| Cmpd | | Energy | Energy | Energy |
| No. | Structure | (eV) | Level (eV) | Level (eV) |

Host Compound A

| | | | | |
|---|---|---|---|---|
| 701a | 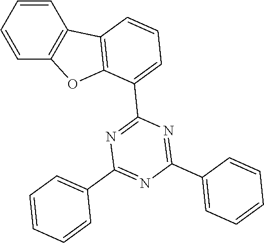 [SMILES: c1ccc(-c2nc(-c3ccccc3)nc(-c3cccc4c3oc3ccccc34)n2)cc1] | 2.86 | −6.11 | −1.87 |
| 7.2a | 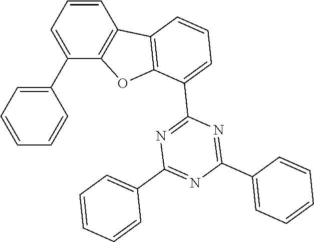 [SMILES: c1ccc(-c2nc(-c3ccccc3)nc(-c3cccc4c3oc3c(-c5ccccc5)cccc34)n2)cc1] | 2.86 | −5.91 | −1.83 |

Host Compound B

| | | | | |
|---|---|---|---|---|
| 751b | 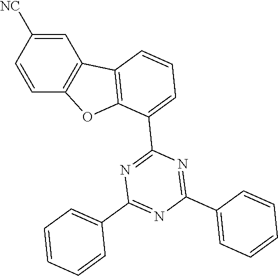 [SMILES: N#Cc1ccc2oc3c(-c4nc(-c5ccccc5)nc(-c5ccccc5)n4)cccc3c2c1] | 2.90 | −6.57 | −2.14 |
| 752b | 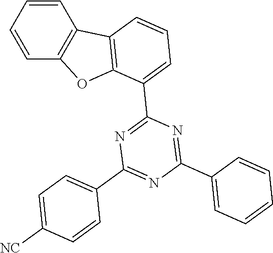 [SMILES: N#Cc1ccc(-c2nc(-c3ccccc3)nc(-c3cccc4c3oc3ccccc34)n2)cc1] | 2.80 | −6.28 | −2.37 |
| 753b | 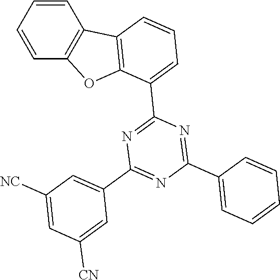 [SMILES: N#Cc1cc(C#N)cc(-c2nc(-c3ccccc3)nc(-c3cccc4c3oc3ccccc34)n2)c1] | 2.77 | −6.32 | −2.55 |
| 751b | 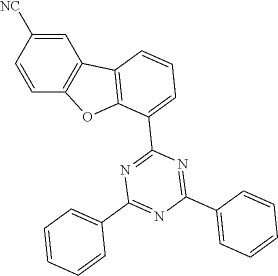 [SMILES: N#Cc1ccc2oc3c(-c4nc(-c5ccccc5)nc(-c5ccccc5)n4)cccc3c2c1] | 2.90 | −6.57 | −2.14 |
| 754b | 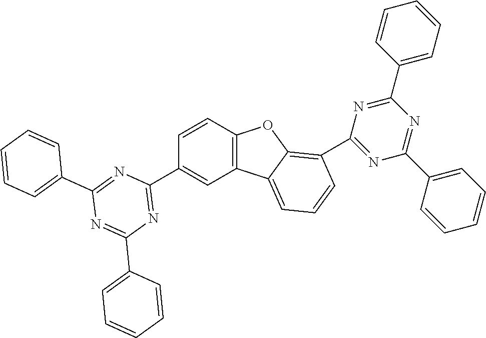 [SMILES: c1ccc(-c2nc(-c3ccccc3)nc(-c3ccc4oc5c(-c6nc(-c7ccccc7)nc(-c7ccccc7)n6)cccc5c4c3)n2)cc1] | 2.85 | −6.20 | −1.95 |
| 755b | 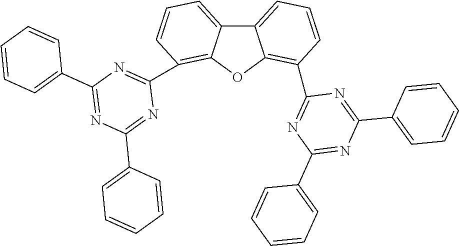 [SMILES: c1ccc(-c2nc(-c3ccccc3)nc(-c3cccc4c3oc3c(-c5nc(-c6ccccc6)nc(-c6ccccc6)n5)cccc34)n2)cc1] | 2.84 | −6.16 | −1.89 |
| 756b | 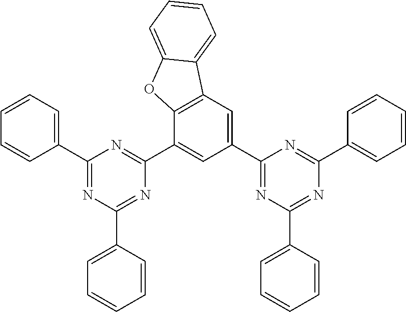 [SMILES: c1ccc(-c2nc(-c3ccccc3)nc(-c3cc(-c4nc(-c5ccccc5)nc(-c5ccccc5)n4)c4oc5ccccc5c4c3)n2)cc1] | 2.83 | −6.19 | −1.99 |

<Requirements (12 and (13)>

In an aspect of the organic EL element of the present invention, preferably the host compounds A and B satisfy the following Requirements (12) and (13) besides the above described Requirement (11).

Excited Triplet State Energies of Host Compounds A and B(T₁ Energies)≥3.0 eV (12)

When both T₁ energies of the host compounds A and B are 3.0 eV or more, the host compounds A and B are hardly converted to quenchers of the phosphorescent material, thereby more elongating a lifetime of the element. Thus, it is preferable to set the T₁ energies of the host compounds A and B to 3.0 eV or more. From the viewpoint of more elongating a lifetime of the element, more preferably the T₁ energy is set to 3.03 eV or more, and more preferably 3.05 eV or more. Here, the upper limit is not specifically limited. However, the value is preferably set to 3.2 eV or less from the viewpoint of stability of the compounds.

Note, even though only one of the host compounds A and B has the T₁ energy of 3.0 eV or more, the above effect can be exerted. However, if both the host compounds A and B have the T₁ energies of 3.0 eV or more, the above effect can be enhanced more greatly. Therefore, preferably both the host compounds A and B have the T₁ energies of 3.0 eV or more.

[LUMO Energy Level of Host Compound A]−[LUMO Energy Level of Host Compound B]≥0.15 eV. (13)

If a value of the equation in Requirement (13) is 0.15 eV or more, electron mobility inside the luminescent layer is decreased, a luminescent area becomes wider, and a lifetime of the element tends to be longer. Therefore, preferably the value of the equation in Requirement (13) is set to 0.15 eV or more. From the viewpoint of more elongating the lifetime of the element, preferably the value is set to 0.20 eV or more, more preferably 0.22 eV or more. Herein, the upper limit is not specifically defined. However, preferably the value is set to 0.6 eV or less from the viewpoint of carrier balance.

<Requirements (14)˜(16)>

In an aspect of the organic EL element of the present invention, preferably the phosphorescent compounds and the host compounds A and B satisfy the following Requirements (14)˜(16) besides the above described Requirement (11).

A luminescence maxim wavelength of luminescence spectrum in a solution of the phosphorescent compound is 470 nm or less. (14)

Setting the luminescence maximum wavelength of luminescence spectrum in a solution of the phosphorescent compound to 470 nm or less can improve a color gamut of the element. Therefore, preferably the luminescence maximum wavelength of luminescence spectrum in a solution of the phosphorescent compound is set to 470 nm or less. From the viewpoint of improving the color gamut of the element, more preferably the luminescence maximum wavelength is set to 465 nm or less, further more preferably 460 nm or less. Here, the lower limit is not specifically defined. However, the luminescence maximum wavelength is preferably set to 435 nm or more from the viewpoint of stability of the compound

The luminescence spectrum in the solution can be obtained, for example, by fluorescence spectrum generated by irradiating the solution prepared by dissolving a dopant in a non-polar solvent with excitation light. More specifically, for example, a dopant is dissolved in 2-methyltetrahydrofuran, and fluorescence spectrum is measured by Hitachi F-7000.

[HOMO Energy Level of Phosphorescent Compound]−[HOMO Energy Level of Host Compound B]≥0.35 eV. (15)

Setting a value of the equation in Requirement (15) to 0.35 or more increases a hole trapping ability of the phosphorescent compound, thereby facilitating adjustment of hole mobility. Thus, preferably the value of the equation in Requirement (15) is set to 0.35 eV or more. From the viewpoint of more facilitating adjustment of the hole mobility, more preferably the value is set to 0.5 eV or more, and further more preferably 0.65 eV or more. Here, the upper limit of the value is not specifically defined. However, preferably the value is set to 1.5 eV or less from the viewpoints of carrier balance and hole injection ability.

A ratio of the host compound A to the host compound B is in the range of 10:90˜90:10. (16)

Setting a ratio of the host compound A to the host compound B to in the range of 10:90˜90:10 facilitates improvement in the stability of film quality and adjustment of the hole mobility. Thus, preferably the ratio of the host compound A to the host compound B is set to in the range of 10:90˜90:10. The ratio is more preferably set to in the range of 30:70˜70:30, or further more preferably 40:60˜60:40 from the viewpoints of more improving the stability of film quality and adjusting the hole mobility.

<<Summary of Organic Electroluminescent Element>>

An organic electroluminescent element of the present invention includes a luminescent layer sandwiched between an anode and a cathode, and a plurality of organic layers including the luminescent layer.

[Configuration Layers of Organic EL Element]

As a representative element configuration of the organic EL element of the present invention, the following configurations are included. However, the present invention is not limited to those configurations.

(1) Anode/Electron Blocking Layer/Luminescent Layer/Hole Blocking Layer/Electron Transport Layer/Cathode

(2) Anode/Hole Transport Layer/Electron Blocking Layer/Luminescent Layer/Hole Blocking Layer/Cathode

(3) Anode/Hole Transport Layer/Electron Blocking Layer/Luminescent Layer/Hole Blocking Layer/Electron Transport Layer/Cathode

(4) Anode/Hole Transport Layer/Electron Blocking Layer/Luminescent Layer/Hole Blocking Layer/Electron Transport Layer/Electron Injection Layer/Cathode

(5) Anode/Hole Injection Layer/Hole Transport Layer/Electron Blocking Layer/Luminescent Layer/Hole Blocking Layer/Electron Transport Layer/Cathode

(6) Anode/Hole Injection Layer/Hole Transport Layer/Electron Blocking Layer/Luminescent Layer/Hole Blocking Layer/Electron Transport Layer/Electron Injection Layer/Cathode

(7) Anode/Hole Transport Layer/Luminescent Layer/Hole Blocking Layer/Electron Transport Layer/Cathode

(8) Anode/Hole Injection Layer/Hole Transport Layer/Luminescent Layer/Hole Blocking Layer/Electron Transport Layer/Electron Injection Layer/Cathode

(9) Anode/Hole Transport Layer/Electron Blocking Layer/Luminescent Layer/Electron Transport Layer/Cathode

(10) Anode/Hole Injection Layer/Hole Transport Layer/Electron Blocking Layer/Luminescent Layer/Electron Transport Layer/Electron Injection Layer/Cathode

In the above configurations, the configuration (6) is preferably used. However, the present invention is not limited thereto.

The luminescent layer used in the present invention is formed of a monolayer or multiple layers. If the luminescent layer is formed of multiple layers, a non-luminescent intermediate layer may be provided between the respective luminescent layers. Examples of the luminescent layer formed of multiple layers include the following configurations. However, the present invention is not limited to those examples.

(11) Anode/Hole Injection Layer/Hole Transport Layer/Electron Blocking Layer/Blue Luminescent Layer/Green-Red Luminescent Layer/Hole Blocking Layer/Electron Transport Layer/Electron Injection Layer/Cathode

(12) Anode/Hole Injection Layer/Hole Transport Layer/Electron Blocking Layer/Green-Red Luminescent Layer/Blue Luminescent Layer/Hole Blocking Layer/Electron Transport Layer/Electron Injection Layer/Cathode

(13) Anode/Hole Injection Layer/Hole Transport Layer/Electron Blocking Layer/Green-Red Luminescent Layer/Intermediate Layer/Blue Luminescent Layer/Hole Blocking Layer/Electron Transport Layer/Electron Injection Layer/Cathode

When the element is made as a white luminescent element, the configuration (12) is preferably used for the invention of the claim 1, and the configuration (11) is preferably used for the invention of the claim 2.

Note, as necessity, a hole blocking layer (i.e., also called a hole barrier layer) or an electron injection layer (i.e., also called a cathode buffer layer) may be provided between the luminescent layer and the cathode. Further, as necessity, an electron blocking layer (i.e., also called an electron barrier layer) or a hole injection layer (i.e., also called anode buffer layer) may be provided between the luminescent layer and the anode.

Here, the electron transport layer is a layer having a function for transporting electrons, and includes the electron injection layer and the hole blocking layer in a broad sense. Further, the electron transport layer may be formed of multiple layers.

The hole transport layer used in the present invention is a layer having a function for transporting holes, and includes the hole injection layer and the electron blocking layer in a broad sense. Further, the hole transport layer may be formed of multiple layers.

(Tandem Structure)

Further, the organic EL element of the present invention may be an element having a so-called tandem structure which is made by stacking a plurality of luminescent units each of which includes at least one luminescent layer.

A representative element configuration having a tandem structure includes the following examples.

Anode/First Luminescent Unit/Second Luminescent Unit/Third Luminescent Unit/Cathode

Anode/First Luminescent Unit/Intermediate Layer/Second Luminescent Layer/Intermediate Layer/Third Luminescent Layer/Cathode

Herein, the first luminescent unit, the second luminescent unit and the third luminescent unit may be the same all together or different respectively. Further, two luminescent units may be the same and the remaining one may be different therefrom.

Moreover, the third luminescent layer may be omitted, while another luminescent layer or intermediate layer may be further provided between the third luminescent layer and an electrode.

A plurality of the luminescent units may be directly stacked or stacked via an intermediate layer. The intermediate layer is generally called an intermediate electrode, an intermediate conductive layer, a charge generation layer, an electron extracting layer, a connection layer, or an intermediate insulating layer. Known materials and configurations may be used for the intermediate layer as long as the layer has a function for supplying electrons to an adjacent layer located at the anode side, and holes to an adjacent layer located at the cathode side.

Materials used for the intermediate layer include, for example, a conductive inorganic compound layer such as ITO (indium-tin oxide), IZO (indium-zinc oxide), ZnO₂, TiN, ZrN, HfN, TiOx, VOx, CuI, InN, GaN, CuAlO₂, CuGaO₂, SrCu₂O₂, LaB₆, RuO₂, and Al; a bilayer such as Au/Bi₂O₃; a multilayer such as SnO₂/Ag/SnO₂, ZnO/Ag/ZnO, Bi₂O₃/Au/Bi₂O₃, TiO₂/TiN/TiO₂, TiO₂/ZrN/TiO₂; a conductive organic substance layer such as fullerenes like Co, etc.; and a conductive organic compound layer such as metallophthalocyanines, metalloporphyrins, non-metalloporphyrins. However the present invention is not limited to those materials.

A preferable configuration inside the luminescent unit includes, for example, the configurations shown in the representative element configurations (1)˜(13) as mentioned hereinbefore from which a cathode and an anode are omitted. However, the present invention is not limited to those configurations.

Examples of the tandem type organic EL element include, for example, element configurations and configuration materials described in U.S. Pat. Nos. 6,337,492, 7,420,203, 7,473,923, 6,872,472, 6,107,734, 6,337,492, WO2005/009087, Japanese Unexamined Patent Application Publication No. 2006-228712, Japanese Unexamined Patent Application Publication No. 2006-24791, Japanese Unexamined Patent Application Publication No. 2006-49393, Japanese Unexamined Patent Application Publication No. 2006-49394, Japanese Unexamined Patent Application Publication No. 2006-49396, Japanese Unexamined Patent Application Publication No. 2011-96679, Japanese Unexamined Patent Application Publication No. 2005-340187, Japanese Patent Publication No. 4711424, Japanese Patent Publication No. 3496681, Japanese Patent Publication No. 3884564, Japanese Patent Publication No. 4213169, Japanese Unexamined Patent Application Publication No. 2010-192719, Japanese Unexamined Patent Application Publication No. 2009-076929, Japanese Unexamined Patent Application Publication No. 2008-078414, Japanese Unexamined Patent Application Publication No. 2007-059848, Japanese Unexamined Patent Application Publication No. 2003-272860, Japanese Unexamined Patent Application Publication No. 2003-045676 and WO2005/094130 or the like. However, the present invention is not limited to those examples.

[Organic Layer]

In the above described element configurations, a layer from which an anode and a cathode are omitted is also called an “organic layer”.

The organic EL element of the present invention includes a plurality of the above described organic layers.

Note, each of the organic layers is simply called an “organic layer” if there is no specific necessity for differentiating those organic layers.

Hereinafter, each of the organic layers will be described in detail.

<Luminescent Layer>

The luminescent layer used in the present invention is sandwiched between the anode and cathode, and contains at least one type of phosphorescent compound (i.e., a dopant) as described later and the above described host compounds A and B.

The luminescent layer used in the present invention is a layer that emits light via recombination of electrons and holes injected from electrodes, or an electron transport layer and a hole transport layer.

A total thickness of the luminescent layer is not specifically limited. However, preferably the total thickness is adjusted in the range of 2 nm˜5 μm, more preferably 2˜200 nm, and further more preferably 5˜100 nm, from the viewpoints of homogeneity of the film, prevention of unnecessary application of a high voltage when emitting light, and improvement in stability of a luminescent color against a driving current.

The luminescent layer can be prepared by using a phosphorescent compound and a host compound described later, and deposited via a film coating method, for example, a vacuum deposition method, a wet method (i.e., also called a wet process such as a spin coating method, a casting method, a die coating method, a blade coating method, a roll coating method, a injecting method, a printing method, a spray coating method, a curtain coating method, a LB method (i.e., a Langmuir Blodgett method)) or the like.

(Phosphorescent Compound)

The phosphorescent compound used in the present invention preferably has a luminescence maximum wavelength of luminescence spectrum in a solution of the compound at 470 nm or less.

The phosphorescent compound is a compound of which luminescence emitted from an excited triplet state is observed. More specifically, the phosphorescent compound is defined as a compound emitting phosphorescence at room temperature (i.e., at 25° C.), and a compound having a phosphorescence quantum yield of 0.01 or more at 25° C. Herein, a preferable phosphorescence quantum yield is 0.1 or more.

The above described phosphorescence quantum yield can be measured by a method described in the Experimental Chemistry Course, 4^{th} edition, vol. 7, Spectroscopy II, page 398 (Maruzen, 1992). A phosphorescence quantum yield in a solution can be measured using various solvents. The phosphorescent compound of the present invention is enough to achieve the above described phosphorescence quantum yield (i.e., 0.01 or more) in either of optional solvents. The phosphorescent compound used in the present invention can be appropriately selected and used from known compounds used in a luminescent layer of an organic EL element.

Here, there are two types of principles on emitting light by the phosphorescent compound. One is an energy transfer type in which an excited state of a host compound is generated via recombination of carriers on the host compound through which carries are transported, and transfer of the energy of the excited state to the phosphorescent compound (i.e., a dopant) generates luminescence from the phosphorescent compound. The other is a carrier trap type in which the phosphorescent compound (i.e., a dopant) becomes a carrier trap to cause recombination of carriers on the phosphorescent compound (i.e., a dopant), and generates luminescence from the phosphorescent compound (i.e., a dopant). In either of the types, it needs an essential condition that the energy of the excited state of the phosphorescent compound (i.e., a dopant) is lower than the energy of the excited state of the host compound.

(Examples of Phosphorescent Compound)

Examples of known phosphorescent compounds usable in the present invention include a compound such as a metallic complex described in the following documents.

Nature 395, 151 (1998); Appl. Phys. Lett., 78, 1622 (2001); Adv. Mater., 19, 739 (2007); Chem. Mater., 17, 3532 (2005); Adv. Mater., 17, 1059 (2005); WO2009/100991, WO2007/101842, WO2003/040257, US Patent Application Publication No. 2006/835469, US Patent Application Publication No. 2006/020219, US Patent Application Publication No. 2007/0087321, US Patent Application Publication No. 2005/0244673; Inorg. Chem., 40, 1704 (2001); Chem. Mater., 16, 2480 (2004); Adv. Mater., 16, 2003 (2004); Angew. Chem. Int. Ed., 2006, 45, 7800; Appl. Phys. Lett., 86, 153505 (2005); Chem. Lett., 34, 592 (2005); Chem. Commun., 2906 (2005); Inorg. Chem., 42, 1248 (2003); WO2009/000673, WO2002/015645, WO2009/000673, US Patent Application Publication No. 2002/0034656, US Patent Publication No. 7332232, US Patent Application Publication No. 2009/0108737, US Patent Application Publication No. 2009/0039776, U.S. Pat. Nos. 6,921,915, 6,687,266, US Patent Application Publication No. 2007/0190359, US Patent Application Publication No. 2006/0008670, US Patent Application Publication No. 2009/0165846, US Patent Application Publication No. 2008/0015355, U.S. Pat. Nos. 7,250,226, 7,396,598, US Patent Application Publication No. 2006/0263635, US Patent Application Publication No. 2003/0138657, US Patent Application Publication No. 2003/0152802, U.S. Pat. No. 7,090,928; Angew. Chem. Int. Ed., 47, 1 (2008); Chem. Mater., 18, 5119 (2006); Inorg. Chem., 46, 4308 (2007); Organometallics, 23, 3745 (2004); Appl. Phys. Lett., 74, 1361 (1999); WO2002/002714, WO2006/009024, WO2006/056418, WO2005/019373, WO2005/123873, WO2005/123873, WO2007/004380, WO2006/082742, US Patent Application Publication No. 2006/0251923, US Patent Application Publication No. 2005/0260441, U.S. Pat. Nos. 7,393,599, 7,534,505, 7,445,855, US Patent Application Publication No. 2007/0190359, US Patent Application Publication No. 2008/0297033, U.S. Pat. No. 7,338,722, US Patent Application Publication No. 2002/0134984, U.S. Pat. No. 7,279,704, US Patent Application Publication No. 2006/098120, US Patent Application Publication No. 2006/103874, WO2005/076380, WO2010/032663, WO2008/140115, WO2007/052431, WO2011/134013, WO2011/157339, WO2010/086089, WO2009/113646, WO2012/020327, WO2011/051404, WO2011/004639, WO2011/073149, WO2012/228583, US Patent Application Publication No. 2012/212126, Japanese Unexamined Patent Application Publication No. 2012-069737, Japanese Unexamined Patent Application Publication No. 2012-195554, Japanese Unexamined Patent Application Publication No. 2009-114086, Japanese Unexamined Patent Application Publication No. 2003-81988, Japanese Unexamined Patent Application Publication No. 2002-302671, Japanese Unexamined Patent Application Publication No. 2002-363552, Japanese Unexamined Patent Application Publication No. 2009-231516, WO2012/112853, Japanese Patent Publication No. 5124942, Japanese Patent Publication No. 4784600, and Japanese Unexamined Patent Application Publication No. 2010-47764 or the like.

In the present invention, the phosphorescent compound may be used in combination with a plurality types of compounds in the range without influencing the effect of the present invention.

Hereinafter, examples of the phosphorescent compound used in the present invention will be described more specifically. However, the present invention is not limited to those examples.

TABLE 8

| | | HOMO | LUMO | |
|---|---|---|---|---|
| | | Energy | Energy | |
| | | Level | Level | λ max |
| | Phosphorescent Compound | (eV) | (eV) | (nm) |
| D-1 | 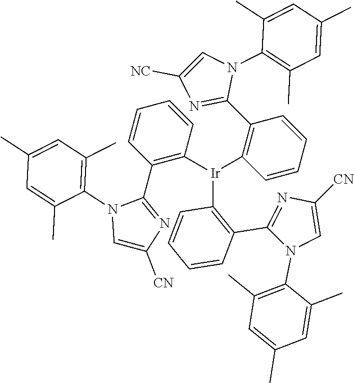 | −4.83 | −0.99 | 464 |
| D-2 | 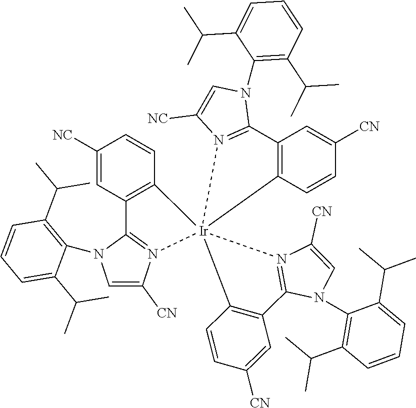 | −5.76 | −1.81 | 456 |
| D-3 | 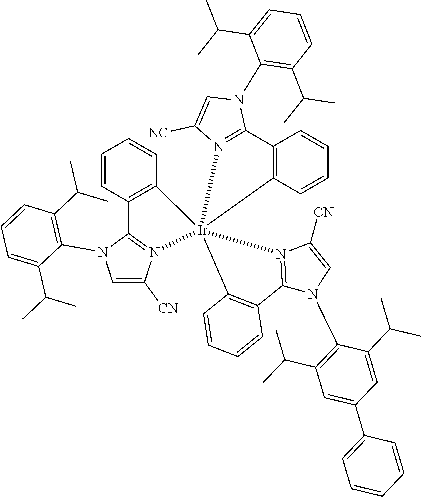 | −4.92 | −1.08 | 465 |

TABLE 9

| | | HOMO | LUMO | |
|---|---|---|---|---|
| | | Energy | Energy | |
| | | Level | Level | λ max |
| | Phosphorescent Compound | (eV) | (eV) | (nm) |
| D-4 | 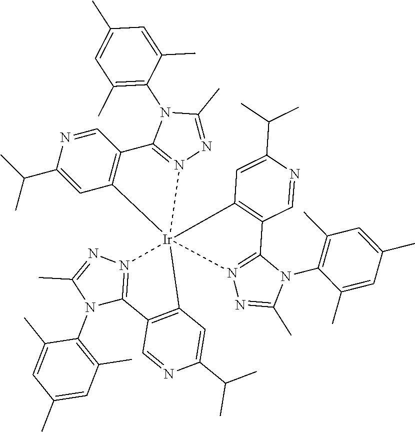 | −4.97 | −0.88 | 437 |
| D-5 | 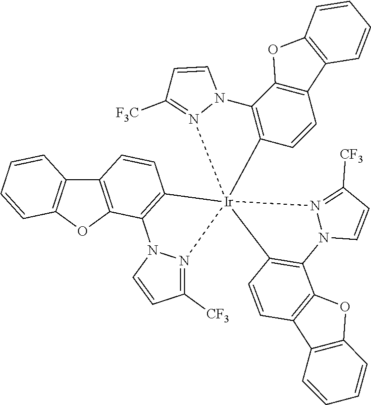 | −5.16 | −1.10 | 454 |
| D-6 | 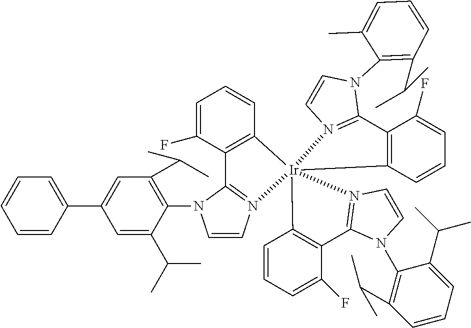 | −4.91 | −1.02 | 465 |

TABLE 10

| | | HOMO | LUMO | |
|---|---|---|---|---|
| | | Energy | Energy | |
| | | Level | Level | λ max |
| | Phosphorescent Compound | (eV) | (eV) | (nm) |
| D-7 | 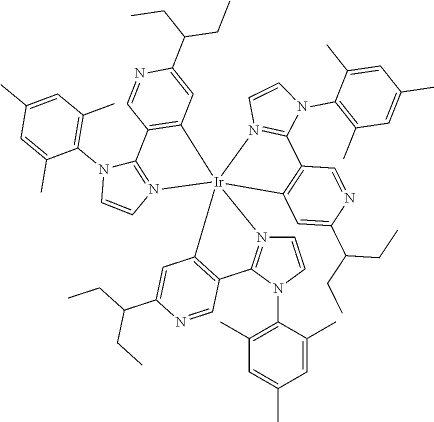 | −4.96 | −0.90 | 442 |
| D-8 | 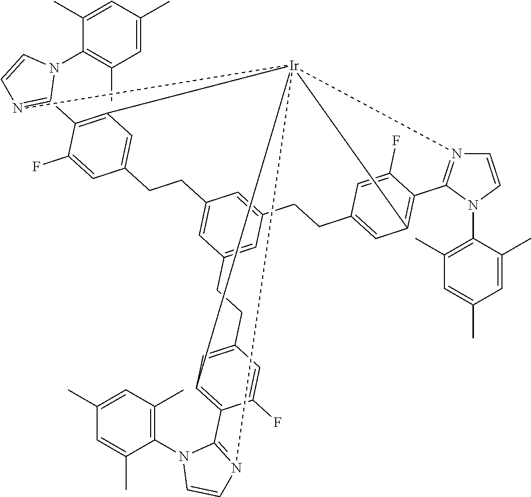 | −4.73 | −0.82 | 465 |
| D-9 | 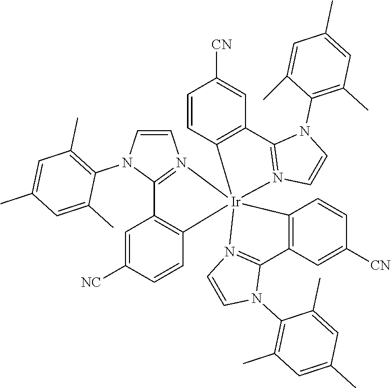 | −5.31 | −1.39 | 462 |

TABLE 11

| | | HOMO | LUMO | |
|---|---|---|---|---|
| | | Energy | Energy | |
| | | Level | Level | λ max |
| | Phosphorescent Compound | (eV) | (eV) | (nm) |
| D-10 | 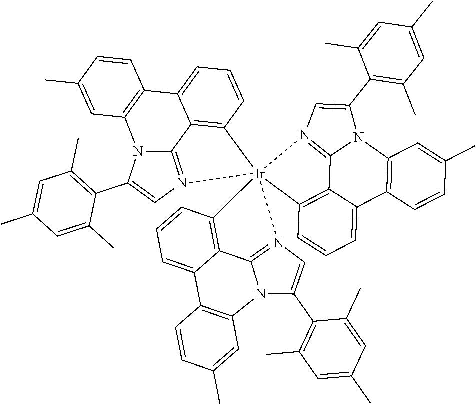 | −4.52 | −0.92 | 463 |
| D-11 | 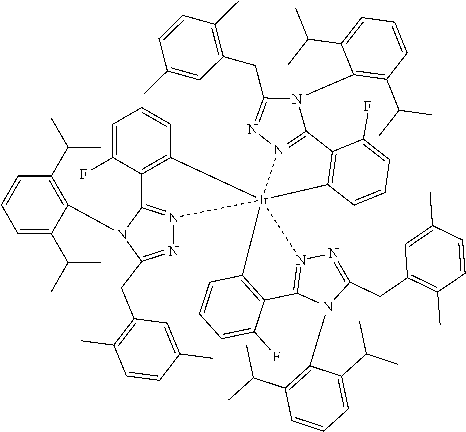 | −4.96 | −1.08 | 456 |
| D-12 | 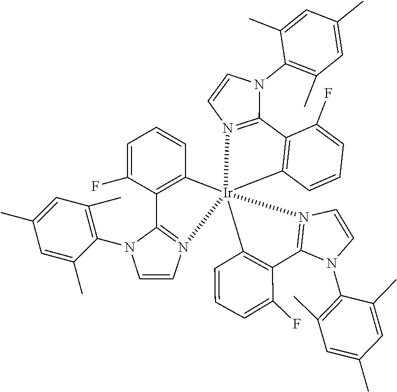 | −4.82 | −0.92 | 465 |
| D-13 | 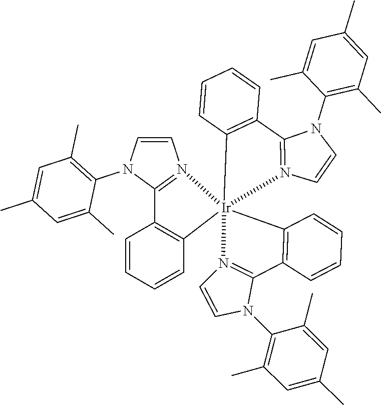 | −4.33 | −0.55 | 466 |

(Host Compound)

In the present invention, the host compound A and the host compound B are used. The host compound A and the host compound B have been described hereinbefore. Here, other items of the host compound A and the host compound B will be described.

The host compound used in the present invention is a compound mainly playing a role of injecting and transporting charges in the luminescent layer. In the organic EL element, substantially no luminescence from the luminescent layer is observed.

The host compound is a compound preferably having a phosphorescence quantum yield of less than 0.1 at room temperature (25° C.), more preferably a compound having a phosphorescence quantum yield of less than 0.01. Further, a mass ratio of the host compound in the luminescent layer is preferably 20% or more per compounds contained in the luminescent layer.

Further, preferably the excited state energy of the host compound is higher than the excited state energy of the phosphorescent compound contained in the same layer.

Preferably, the host compound has a hole transport ability or an electron transport ability, and simultaneously has a high glass transition temperature (Tg) from the viewpoints of prevention of wavelength elongation of the luminescence, and stable operation when the organic EL element is driven at a high temperature or against heat generated when the element is driven. More preferably, Tg is 90° C. or more, and further more preferably 120° C.

Here, the glass transition temperature (Tg) is a value measured by using DSC (Differential Scanning Colorimetry) following JIS-K-7121.

In the present invention, the host compound may be used in combination with a plurality types of compounds in the range without influencing the effect of the present invention.

<Hole Blocking Layer>

The hole blocking layer used in the present invention is located adjacent to the luminescent layer at the cathode side.

The “hole blocking layer located adjacent to the luminescent layer at the cathode side” means a layer having a function of an electron transport layer in a broad sense. Preferably, the above hole blocking layer is formed of a compound having a function for transporting electrons but a poor function for transporting holes. The hole blocking layer can improve a recombination probability between electrons and holes by transporting electrons and blocking holes.

Preferably, the hole blocking layer used in the present invention has a thickness in the range of 3˜100 nm, more preferably 5˜30 nm.

A compound used for the hole blocking layer needs to have the electron transport ability but a poor ability for transporting holes. Specifically, a compound used for the electron transport layer described later together with a compound used for the host compound described above are preferably used for the hole blocking layer.

Further, as necessity, a compound used for the electron transport layer described later can be used as a compound contained in the hole blocking layer used in the present invention.

For example, such a compound includes, for example, a nitrogen-containing aromatic heterocycle derivative such as a carbazole derivative, an azacarbazole derivative, a pyridine derivative, a triazine derivative; and a dibenzofuran derivative or the like.

<Electron Transport Layer>

In the present invention, the electron transport layer just has to be made of a compound having a function for transporting electrons, and have a function for conveying electrons injected from the cathode to the luminescent layer.

A total thickness of the electron transport layer is not specifically limited. However, usually the total thickness is in the range of 2 nm˜5 μm, preferably 2˜500 nm, and more preferably 5˜200 nm.

Further, it is known that in an organic EL element, light directly extracted from a luminescent layer interferes with light extracted after reflected by an electrode located opposite to another electrode from which light is extracted, when light generated by the luminescent layer is extracted. When light is reflected by a cathode, appropriate adjustment of the total thickness of the electron transport layer in the range of 5 nm˜200 mm enables the interference effect to be efficiently used.

On the other hand, the large the thickness of the electron transport layer becomes, the greater the voltage tends to rise. Thus, when the thickness is large, preferably the electron transport layer has electron mobility of 10⁻⁵ cm²/Vs or more.

A compound used for the electron transport layer (i.e., hereinafter, called an electron transport material) just has to have either of the electron injection or transport ability or the hole blocking ability. Any one selected from conventionally known compounds may be used for the electron transport material.

For example, such a compound includes a nitrogen-containing aromatic heterocycle derivative (e.g., a carbazole derivative, an azacarbazole derivative (i.e., a ring system where at least one carbon atom forming the carbazole ring is replaced by a nitrogen atom), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a tetrazole derivative, a benzimidazole derivative, a benzoxazole derivative, a benzthiazole derivative); a dibenzofuran derivative, a dibenzothiophene derivative, a silole derivative, an aromatic hydrocarbon cycle derivative (e.g., a naphthalene derivative, an anthracene derivative and a triphenylene derivative) or the like.

Further, the electron transport material includes the compounds described in the examples of the host compound as mentioned above.

Moreover, the following compounds may be used as the electron transport material, including a metallic complex of which ligand has a quinolinol skeleton or a dibenzoquinolinol skeleton, for example, tris(8-quinolinol)aluminum (Alq), tris(5,7-dichloro-8-quinolinol)aluminum, tris(5, 7-dibromo-8-quinolinol)aluminum, tris(2-methyl-8-quinolinol)aluminum, tris(5-methyl-8-quinolinol)aluminum, bis(8-quinolinol)zinc (Znq). Furthermore, a metallic complex made by replacing a center metal of the above metallic complexes by In, Mg, Cu, Ca, Sn, Ga or Pb is also used for the electron transport material.

In addition to the above compounds, a metal free phthalocyanine or a metal phthalocyanine, or a derivative of which terminal group is replaced by an alkyl group or a sulfonic acid group may be used as the electron transport material. Further, a distyrylpyrazine derivative exemplified as a material for the luminescent layer may be used for the electron transfer material. Moreover, an inorganic semiconductor such as n-type Si, n-type SiC may be used for the electron transport material similarly to the hole injection layer and the hole transport layer.

Furthermore, a polymer compound in which the above materials are introduced in the polymer chain, or a polymer compound in which the above materials are used as the main chain of the polymer may be used for the electron transport material.

As for the electron transport layer used in the present invention, a high n-type (i.e., electron rich) electron transport layer may be formed by doping the electron transport layer with a dope material serving as a guest compound. Such a dope material includes an n-type dopant such as a metallic compound including a metallic complex and a halogenated metal. Examples of the electron transport layer having the above described composition include those described in, for example, Japanese Unexamined Patent Application Publication No. H4-297076, Japanese Unexamined Patent Application Publication No. H10-270172, Japanese Unexamined Patent Application Publication No. 2000-196140, Japanese Unexamined Patent Application Publication No. 2001-102175, and J. Appl. Phys., 95, 5773 (2004) or the like.

Examples of known and preferable electron transport materials used in the organic EL element of the present invention include the compounds described in the following documents. However, the present invention is not limited to those examples.

U.S. Pat. Nos. 6,528,187, 7,230,170, US Patent Application Publication No. 2005/0025993, US Patent Application Publication No. 2004/00360077, US Patent Application Publication No. 2009/0115316, US Patent Application Publication No. 2009/0101870, US Patent Application Publication No. 2009/0179554, WO2003/060956, WO2008/132085, Appl. Phys. Lett., 75, 4 (1994), Appl. Phys. Lett., 79, 449 (2001), Appl. Phys. Lett., 81, 162 (2002), Appl. Phys. Lett., 79, 156 (2001), U.S. Pat. No. 6,796,4293, US Patent Application Publication No. 2009/030202, WO2004/080975, WO2004/063159, WO2005/085387, WO2006/067931, WO2007/086552, WO2008/114690, WO2009/069442, WO2009/066779, WO2009/054253, WO2011/086935, WO2010/150593, WO2010/047707, European Patent Application Publication No. 2311826, Japanese Unexamined Patent Application Publication No. 2010-251675, Japanese Unexamined Patent Application Publication No. 2009-209133, Japanese Unexamined Patent Application Publication No. 2009-124114, Japanese Unexamined Patent Application Publication No. 2008-277810, Japanese Unexamined Patent Application Publication No. 2006-156445, Japanese Unexamined Patent Application Publication No. 2005-340122, Japanese Unexamined Patent Application Publication No. 2003-45662, Japanese Unexamined Patent Application Publication No. 2003-31367, Japanese Unexamined Patent Application Publication No. 2003-282270, and WO2012/115034 or the like.

Note, the compounds described in the examples of the host compound may be used for the electron transport material.

Here, the electron transport material may be used alone, or in combination with a plurality kinds of the materials.

<Electron Injection Layer>

The electron injection layer is a layer provided between the cathode and the organic layer to decrease the driving voltage and improve the luminescent brightness as necessity. The electron injection layer is described in detail in “Organic EL Element and Frontier of Industrialization (NTS Inc., Nov. 30, 1998)”, Vol. 2, Chapter 2, “Electrode Material” (pp. 123-166).

Details of the electron injection layer are also described in Japanese Unexamined Patent Application Publication No. H6-325871, Japanese Unexamined Patent Application Publication No. H9-17574, and Japanese Unexamined Patent Application Publication No. 10-74586. Specifically, such an electron injection layer includes a metal buffer layer represented by strontium and aluminum; an alkali metal compound buffer layer represented by lithium fluoride and potassium fluoride; an alkali earth metal compound buffer layer represented by magnesium fluoride and cesium fluoride; and an oxide buffer layer represented by aluminum oxide or the like. Preferably, the above mentioned buffer layer (i.e., preferably an injection layer is an extremely thin film, and a thickness thereof is preferably in the range 0.1 nm˜5 μm depending on the raw materials.

<Electron Blocking Layer>

The electron blocking layer of the present invention is located adjacent to the luminescent layer at the anode side.

The “electron blocking layer located adjacent to the luminescent layer at the anode side” in the present invention is preferably formed of a compound having a function transporting holes but a poor function for transporting electrons. Here, the function for transporting holes and blocking electrons can improve a recombination probability between electrons and holes.

Further, the configurations of the electron transport layer as mentioned above may be used for the materials contained in the electron blocking layer used in the present invention as necessity.

The electron blocking layer preferably has a thickness in the range of 3˜100 nm, more preferably 5˜30 nm.

<Hole Injection Layer>

The hole injection layer (i.e., also called an “anode buffer layer”) used in the present invention is a layer provided between the anode and the luminescent layer in order to decrease the driving voltage and improve the luminescence brightness. Such a hole injection layer is described in detail in “Organic EL Element and Frontier of Industrialization (NTS Inc., Nov. 30, 1998)”, Vol. 2, Chapter 2, “Electrode Material” (pp. 123-166).

In the present invention, the hole injection layer may be provided as necessity, and arranged between the anode and the luminescent layer, or between the anode and the hole transport layer as mentioned above.

The hole injection layer is described in detail in Japanese Unexamined Patent Application Publication No. H9-45479, Japanese Unexamined Patent Application Publication No. H9-260062, and Japanese Unexamined Patent Application Publication No. H8-288069. Materials used for the hole injection layer include, for example, compounds used for the above described electron blocking layer.

Among those compounds, preferable one includes a phthalocyanine derivative represented by a copper phthalocyanine; a hexaazatriphenylene derivative described in Japanese Unexamined Patent Application Publication No. 2003-519432 and Japanese Unexamined Patent Application Publication No. 2006-135145; a metal oxide represented by vanadium oxide; a conductive polymer such as amorphous carbon, polyaniline (e.g., emeraldine), and polythiophene; an orthometalated complex represented by tris(2-phenylpyridine) indium complex; and a triarylamine derivative or the like.

The compound used for the hole injection layer may be used alone, or in combination with the plurality kinds of compounds.

<Hole Transport Layer>

The hole transport layer is made of a compound having a function for transporting holes, and just has to have a function for conveying holes thus injected from the anode to the luminescent layer.

Here, a total thickness of the hole transport layer is not specifically limited. However, usually the total thickness is in the range of 5 nm˜5 μm, preferably 2 nm˜500 nm, and more preferably 5 nm˜200 nm.

A compound used for the hole transport layer just has either of a function for injecting or transporting holes or a function for blocking electrons, and an optional compound may be selected from conventionally known compounds to be used for the hole transport layer.

For example, such a compound includes a porphyrin derivative, a phthalocyanine derivative, an oxazole derivative, an oxadiazole derivative, a triazole derivative, an imidazole derivative, a pyrazoline derivative, a pyrazoline derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene based derivative such as anthracene and naphthalene, a fluorene derivative, a fluorenone derivative and polyvinyl carbazole, a polymer compound or oligomer in which an aromatic amine is introduced to the main chain or side chains thereof, polysilane, a conductive polymer or oligomer (e.g., PEDOT:PSS, an aniline based copolymer, a polyaniline, and a polythiophene) or the like.

Such a triarylamine derivative includes, for example, a benzidine type compound represented by α-NPD, a starburst type compound represented by MTDATA, and a compound having fluorene or anthracene in a triarylamine linkage core part.

Further, a hexaazatriphenylene derivative described in Japanese Unexamined Patent Application Publication No. 2003-519432 and Japanese Unexamined Patent Application Publication No. 2006-135145 may be similarly used for the hole transport material.

Moreover, a hole transport layer having a high p-type property made by being doped with impurities may be used in the present invention. Such an example is described in Japanese Unexamined Patent Application Publication No. H4-297076, Japanese Unexamined Patent Application Publication No. 200-196140, Japanese Unexamined Patent Application Publication No. 2001-102175, and J. Appl. Phys., 95, 5773 (2004).

Furthermore, a so-called p-type hole transport material and an inorganic compound like p-type Si, p-type SiC described in Japanese Unexamined Patent Application Publication No. H11-251067, J. Huang et. al., Applied Physics Letters, 80, p. 139 (2002) may be used for the hole transport material. Further, an orthometalated organometallic complex having Ir or Pt as the center metal represented by Ir(ppy)₃ is preferably used therefor.

The above described materials can be used for the hole transport material. Herein, preferably used are a triarylamine derivative, a carbazole derivative, an indolocarbazole derivative, an azatriphenylene derivative, an organometallic complex, and a polymer compound or oligomer in which an aromatic amine is introduce into the main chain or side chains thereof.

Examples of known and preferable hole transport materials which are applicable to the organic EL element of the present invention include compounds described in the following documents besides the above described documents. However, the present invention is not limited to those examples.

For example, Appl. Phys. Lett., 69, 2160 (1996), J. Lumin., 72-74, 985 (1997), Appl. Phys. Lett., 78, 673 (2001), Appl. Phys. Lett., 90, 183503 (2007), Appl. Phys. Lett., 51, 913 (1987), Synth. Met., 87, 171 (1997), Synth. Met., 91, 209 (1997), Synth. Met., 111, 421 (2000), SID Symposium Digest, 37, 923 (2006), J. Mater. Chem., 3, 319 (1993), Adv. Mater., 6, 677 (1994), Chem. Mater., 15, 3148 (2003), US Patent Application Publication No. 2003/0162053, US Patent Application Publication No. 2002/0158242, US Patent Application Publication No. 2006/0240279, US Patent Application Publication No. 2008/0220265, US Patent Publication No. 5061569, WO2007/002683, WO2009/0180009, EP650955, US Patent Application Publication No. 2008/0124572, US Patent Application Publication No. 2007/0278938, US Patent Application Publication No. 2008/0106190, US Patent Application Publication No. 2008/0018221, WO2012/115034, Japanese Unexamined Patent Application Publication No. 2003-519434, Japanese Unexamined Patent Application Publication No. 2006-135145, US Patent Application No. 1313/585981 or the like.

Here, the hole transport material may be used alone or in combination with the plurality kinds of materials.

<Inclusion>

The above described organic layer in the present invention may further contain other inclusions.

Such an inclusion is, for example, a halogen element and a halogenated compound of bromine, iodine and chlorine; an alkali metal and an alkali earth metal such as Pd, Ca, Na; a compound and complex of a transition metal; and a salt.

A content of the inclusion may be optionally determined. However, the content is preferably set to 1000 ppm or less per total mass % of the layer in which the inclusion is contained, more preferably 500 ppm or less, and further more preferably 50 ppm or less.

Note, the content is not limited within the range, depending on the purpose for improving the transport ability of electrons and holes, or the purpose for facilitating the energy transfer of excitons.

[Method for Forming Organic Layer]

Next, a method for forming an organic layer (e.g., a hole injection layer, a hole transport layer, an electron blocking layer, a luminescent layer, a hole blocking layer, an electron transport layer and an electron injection layer or the like) will be described more specifically.

A method for forming the organic layer of the present invention is not specifically limited. A conventionally known methods may be used for forming the organic layer, including, for example, a vacuum deposition method, a wet method (or called a wet process) or the like.

The wet method includes a spin coating method, a casting method, an ink jet method, a printing method, a die coating method, a blade coating method, a roll coating method, a spray coating method, a curtain coating method, and a LB method (i.e., a Langmuir Blodgett method) or the like. Herein, a method having the high suitability for a roll-to-roll type process is more preferably, including a die coating method, a roll coating method, an ink jet method, a spray coating method in view of availability of a homogeneous thin film and high producibility.

As for a liquid medium dissolving or dispersing the organic EL material used in the present invention, usable are organic solvents, for example, ketones such as methyl ethyl ketone, cyclohexanone; fatty acid esters like methyl acetate; halogenated hydrocarbons like dichlorobenzene; aromatic hydrocarbons like toluene, xylene, mesitylene, and cyclohexylbenzene; aliphatic hydrocarbons like cyclohexane, decalin, and dodecane; and DMF, DMSO or the like.

Further, a dispersion method includes supersonic dispersion, high shear dispersion, or media dispersion, and all of which can be used for dispersion in the present invention.

Moreover, a different film forming method may be used per layer. When a vapor deposition method is used for forming films, conditions of the vapor deposition are different depending on a type of a compound to be used therefor. However, the following conditions may be appropriately selected, for example, a boat heating temperature in the range 50˜450° C., a vacuum level in the range of 10⁻⁶˜10⁻² Pa, a vapor deposition rate in the range of 0.01˜50 nm/sec, a substrate temperature in the range of −50˜300° C., and a thickness of 0.1 nm˜5 μm, preferably 5˜200 nm.

Preferably, formation of the organic layer used in the present invention is consistently conducted from the hole injection layer to the cathode via one vacuum drawing. However, the organic layer may be once taken out during the whole deposition process, and subjected to a different film forming method. At that time, it is preferable to conduct the film forming method under the atmosphere of dry inert gas.

[Anode]

As for an anode of the organic EL element, preferably used is an electrode material made of a metal, an alloy, an electric conductive compound and the mixture thereof having a large work function (i.e., 4 eV or more, preferably 4.5 eV or more). Examples of those electrode materials include a metal like Au, a conductive transparent material like CuI, indium oxide (ITO), SnO₂ and ZnO. Further, a material capable of producing an amorphous and transparent conductive film like IDIXO (In₂O₃—ZnO) may be used for the electrode material.

Here, the anode may be produced via forming a thin film by depositing or spattering those electrode materials, and then a desirable pattern may be formed thereon by photolithography. Alternatively, when high accuracy of a pattern is not needed (i.e., at a degree of 100 μm or more), such a pattern may be formed via using a desirable shaped mask when depositing or spattering the electrode material.

Further, when a coatable material like an organic conductive compound is used, a wet-type film forming method like a printing method, a coating method may be also used. When luminescence is extracted from the anode, preferably the transparency may be set to more than 10%, and sheet resistance of the anode may be set to several hundreds Ω/□ or less.

A thickness of the anode may depend on the materials. However, the thickness is usually selected from the range of 10 nm˜1 μm, preferably 10 nm˜200 nm.

[Cathode]

As for the cathode, a metal (or called an electron injectable metal) with a small work function (i.e., 4 eV or less), an alloy, an electron conductive compound, and the mixture thereof may be used as an electrode material. Examples of those electrode materials include, for example, sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rear earth metal or the like.

Among those materials, in view of the electron injectability and the durability against oxidation, a mixture of an electron injectable metal and a secondary metal having a work function and stability larger than the electron injectable metal may be preferably used including, for example, a magnesium/silver mixture, a magnesium/aluminum mixture, a magnesium/indium mixture, an aluminum/aluminum oxide (Al₂O₃), a lithium/aluminum mixture, and aluminum or the like.

The cathode may be prepared by forming a thin film via depositing or spattering those electrode materials. Further, sheet resistance of the cathode may be preferably set to several hundreds Ω/□ or less. The thickness is usually selected from the range of 10 nm˜5 μm, preferably 50 nm˜200 mm.

Note, in order to transmit light thus emitted, if either of the anode or the cathode in the organic EL element is transparent or semi-transparent, it is more convenient because the luminescence brightness is improved.

Moreover, after preparing the above described metal film with a thickness of 1˜20 nm for serving as the cathode, a transparent or semi-transparent cathode may be prepared on the metal film by depositing the conductive transparent material listed in the descriptions of the anode. Hence, use of the above described process may produce the organic EL element having both transparent anode and cathode.

[Support Substance]

A support substance (hereinafter, called a base, a substrate, a base material, or a support) used for the organic EL element of the present invention is not specifically limited to types of glass and plastics, and may be transparent or opaque. When luminescence is extracted from a support substrate side, preferably the support substrate is transparent (note: when the support substrate is transparent, it is also called a “transparent substrate”). Such a transparent substrate preferably used herein includes glass, quarts, and a transparent resin film. A particularly preferable support substrate is a resin film capable of providing the organic EL element with flexibility.

Here, known resin films can be used for the resin film. For example, resins described in Japanese Unexamined Patent Application Publication No. 2015-038941, in paragraph 0370 may be preferably used.

On a surface of the resin film, a coating film of an inorganic substance or an organic substance, or a hybrid coating film made of the inorganic and organic substances may be formed. Such a coating film is preferably a gas barrier film having a water permeability (at 25±0.5° C., relative humidity (90±2) % RH) of 0.01 g/(m²/24 h) or less thus measured by a method associated with JIS K 7129-1992. Further, more preferably such a coating film is a high-performance gas barrier film having an oxygen permeability of 1.0×10⁻³ ml/(m²/24 h/atm) or less thus measured by a method associated with JIS K 7126-1987, and water permeability of 1.0×10⁻⁵ g/(m²/24 h) or less.

The opaque support substrate includes, for example, a metal sheet like aluminum or stainless steel, a film or opaque resin substrate, and a substrate made of ceramics.

The organic EL element of the present invention has an externally extracting quantum efficiency of luminescence at room temperature is preferably 1% or more, and more preferably 5% or more.

Here, “Externally Extracting Quantum Efficiency (%)”=“Number of Photons Emitted to Outside of Organic EL Element”/Number of Electrons Passed through Organic EL Element”×100

Further, a hue improvement filter like a color filter may be used in combination, or a color conversion filter may be used in combination which converts a luminescent color from the organic EL element to multiple colors via using a fluorescent material.

<Sealing>

A sealing means used for sealing the organic EL element of the present invention includes, for example, a method for bonding a sealing member to the electrode and support substrate by an adhesive. The sealing member just has to be arranged to cover a display region of the organic EL element, and may have a concave shape or a tubular shape. Further, the transparence and electric insurance thereof are not specifically limited.

More specifically, for example, a sealing member and adhesive described in Japanese Unexamined Patent Application Publication No. 2015-038941, in paragraphs 0379, 0382 and 0383 may be preferably used.

In the present invention, a polymer film and a metal film may be preferably used because the organic EL element can be made as a thin film. Further, preferably the polymer film has an oxygen permeability of 1.0×10⁻³ ml/(m²/24 h/atm) or less thus measured by a method associated with JIS K 7126-1987, and water permeability (at 25±0.5° C., relative humidity (90±2) % RH) of 1.0×10⁻³ g/(m²/24 h) or less thus measured by a method associated with JIS K 7129-1992.

The sealing member is processed to a concave shape by a sandblast process or a chemical etching process or the like.

Further, as described in Japanese Unexamined Patent Application Publication No. 2015-038941, in paragraphs 0384 and 0385, a sealing film may be also preferably prepared by coating the outside of an electrode opposite to the support substrate through an organic layer with the electrode and the organic layer, and forming an inorganic layer or an organic layer so that the layer is adjacent to the support substrate. In this case, a material forming the sealing film jut has to have a function for preventing penetration of substances such as water and oxygen that deteriorate the element. For example, silicon oxide, silicon dioxide, and silicon nitride may be used for materials of the sealing film.

Note, an inert gas such as nitrogen and argon and an inert liquid such as fluorinated hydrocarbon and silicone oil are preferably injected in a gas phase and a liquid phase, into a gap between the sealing member and the display region of the organic EL element. Further, such a gap may be evacuated to a vacuum. Moreover, a moisture-absorbing compound may be also sealed inside the gap.

As for the moisture-absorbing compound, a compound described in Japanese Unexamined Patent Application Publication No. 2015-039841 in paragraph 0387 may be preferably used.

[Protection Film and Protection Sheet]

A protection film or a protection sheet may be provided outside the sealing film or the sealing film thus located opposite to the support substrate through the organic layer, in order to increase the mechanical strength of the element. Particularly, when sealing is conducted by the sealing film, preferably such a protection film or a protection sheet is arranged because the mechanical strength of the sealing film is not necessary high. Here, a material used for the protection film or protection sheet includes a glass plate, a polymer plate-film, a metal plate-film or the like the same as used in the above described sealing. However, in view of weight reduction and thinness of film, a polymer film is preferably used.

[Technique for Improving Light Extraction]

It is generally said that an organic electroluminescent element emits light inside a layer having a refractive index higher than air (i.e., the refractive index in the range of about 1.6˜2.1), and only a degree of 15%˜20% of light can be extracted from the light emitted in the luminescent layer. This is because light entering an interface (i.e., an interface between a transparent substrate and air) at an angle θ larger than a critical angle causes total reflection on the interface and cannot be extracted to the outside of the element. Further, this is because light causes total reflection between a transparent electrode and a transparent substrate or between a luminescent layer and a transparent substrate, and therefore, the light is guided through the transparent electrode or the luminescent layer. Both reasons result in escaping of light toward sides of the element.

A method for improving a light extracting efficiency includes, for example, a method for preventing total reflection on the interface between the transparent substrate and air via forming unevenness on a surface of the transparent substrate (e.g., U.S. Pat. No. 4,774,435), a method for improving the efficiency by making the substrate have light condensability (e.g., Japanese Unexamined Patent Application Publication No. S63-314795), a method for forming a reflection surface on a side of the element (e.g., Japanese Unexamined Patent Application Publication No. H1-220394), a method for forming a reflection preventing film by introducing a flat layer having a middle refraction index between the substrate and the luminescent body (e.g., Japanese Unexamined Patent Application Publication No. S62-172691), a method for introducing a flat layer having a refraction index lower than the substrate between the substrate and the luminescent body (e.g., Japanese Unexamined Patent Application Publication No. 2001-202824) and a method for forming a diffraction grating between any layers of the substrate, the transparent electrode layer and the luminescent layer (including a gap between the substrate and outside) (e.g., Japanese Unexamined Patent Application Publication No. H11-283751) or the like.

[Light Condensing Sheet]

Brightness in a specific direction of the organic electroluminescent element of the present invention may be improved by processing the element so that a microlens array shaped structure is provided at a light extraction side of the support substrate (i.e., a substrate), or combining the element with a so-called light condensation sheet so that light is concentrated in the specific direction, for example, in the front direction opposite to the light emitting surface of the element.

Known materials may be used for such a microlens array and a light condensation sheet. For example, materials described in Japanese Unexamined Patent Application Publication No2015-038941 in paragraphs 0401-0403 are preferably used.

<<Application>>

The organic EL element of the present invention may be applied to a display device, a display, and various light emitting sources.

The light emitting sources include, for example, a light source for a lighting device (e.g., home lighting, car interior lighting); a lighting source for backlight of a watch and a liquid crystal, an advertising signboard, a signal, and an optical storage medium; a light source for an electrophotographic copier, a light source for an optical communication processor; and a light source for an optical sensor. The light emitting sources are not limited to those examples. However, especially backlight of a liquid crystal display can be effectively used for application to the lighting sources.

The organic EL element of the present invention may be subjected to patterning via using a metal mask and inkjet printing during the deposition as necessity. When subjected to patterning, only the electrode may be subjected, only the electrode and the luminescent layer may be subjected, or all the layers of the element may be subjected. For preparing the element, conventionally known methods may be used.

<<One Aspect of Lighting Device in Present Invention>>

Next, an aspect of the lighting device in the present invention provided with the organic EL element of the present invention will be described.

First, a non-luminescent surface of the organic EL element of the present invention was covered by a glass case. A glass support substrate with a thickness of 300 μm is used as a sealing substrate, and then an epoxy based photocurable adhesive (TOAGOSEI CO., LTD., Luxtrack LC0629B) was applied as a sealing material to a periphery of the glass case. The applied glass case was laid over the cathode to be closely fitted to the transparent support substrate (i.e., the glass support substrate). Next, UV light was irradiated from the side of the glass support substrate to cure the sealing material to seal the glass case, whereby a lighting device shown in FIG. 2 is produced.

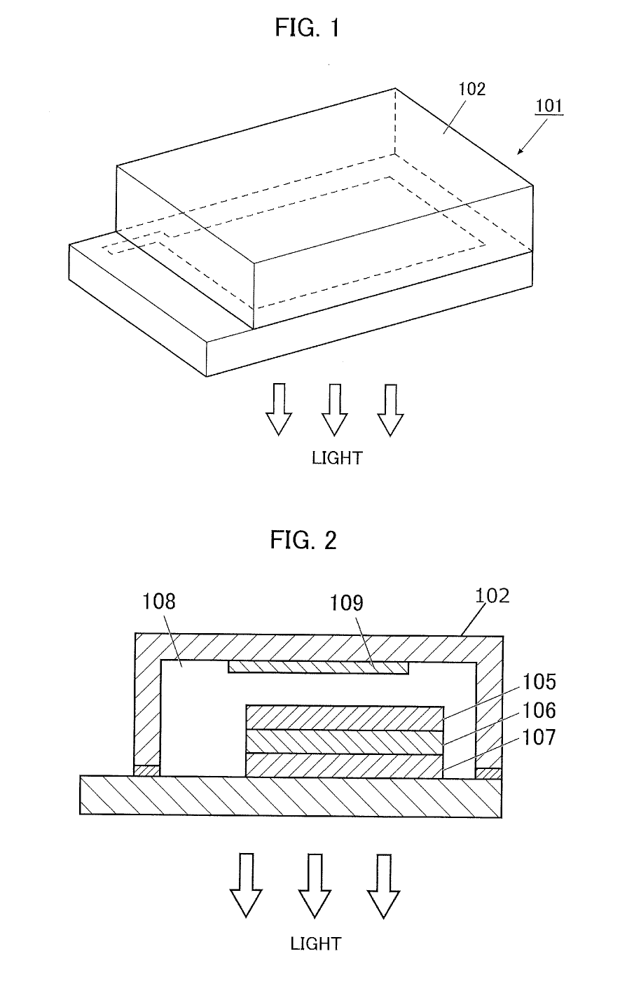

FIG. 1 shows a schematic diagram of the lighting device. Here, the organic EL element 101 of the present invention was covered by a glass case 102 (i.e., sealing operation using a glass case was carried out inside a GB (globe box) under a nitrogen atmosphere (i.e., a highly purified nitrogen gas at the purity of 99.999% or more, without allowing the organic EL element 101 to contact the air)).

FIG. 2 shows a cross-sectional diagram of the lighting device. FIG. 2 shows a cathode 105, a plurality of organic layers 106, and a glass substrate provided with a transparent electrode 107. Note, a nitrogen gas 108 is filled inside the glass case 102, and a moisture capture 109 was arranged therein.

<<Embodiment of Display Device>>

Next, an embodiment of a display in the present invention having the organic EL element of the present invention will be described more specifically.

The display of the present invention may be a monocolor or multicolor device. Here, the multicolor display will be described hereinafter.

In case of the multicolor display, a shadow mask is provided at the time only forming the luminescent layers. A film may be deposited on one side via a vapor deposition method, a casting method, a spin coating method, an inkjet method, and a printing method.

When only the luminescent layer is spin-coated, the method is not specifically limited. However, preferable method includes a vapor deposition method, a casting method, a spin coating method, an inkjet method, and a printing method.

A configuration of the organic EL element mounted in the display is selected from the examples of the configurations of the above described organic EL element as necessity.

Further, a method for producing the display is not specifically limited. The display may be produced by using known methods.

When a DC voltage is applied to a multicolor display, applying a voltage of 2˜40 V as setting the anode to positive polarity and the cathode to negative polarity enables luminescence to be observed. On the contrary, applying the voltage as setting the anode and cathode to the opposite polarities prevents a flow of current, resulting in no emission of luminescence. Further, when an AC voltage is applied to the display, luminescence is emitted only when the anode is a positive condition and the cathode is a negative condition. Note, any waveform of the AC voltage thus applied may be used.

Here, a multicolor display may be used as a display device, a display and various light emitting sources. Use of 3 types of the organic EL elements each of which emits blue, red and green luminescence can realize a full color display.

The display device and display include a television, a personal computer, a mobile apparatus, an AV apparatus, a teletext display, and an information display inside an automobile or the like. The display may be used especially for a display apparatus reproducing a still image and moving image. When the display is used for a display apparatus reproducing a moving image, a driving method may be any one of a simple matrix system (or a passive matrix) and an active matrix system.

The light emitting sources include, for example, a lighting source for a lighting device (e.g., home lighting, car interior lighting); a lighting source for backlight of a watch and a liquid crystal, an advertising signboard, a signal, and an optical storage medium; a lighting source for an electrophotographic copier, a lighting source for an optical communication processor and a lighting source for an optical sensor. However, the light emitting sources are not limited to those examples.

Hereinafter, an example of the display including the organic EL element of the present invention will be described referring to the attached drawings.

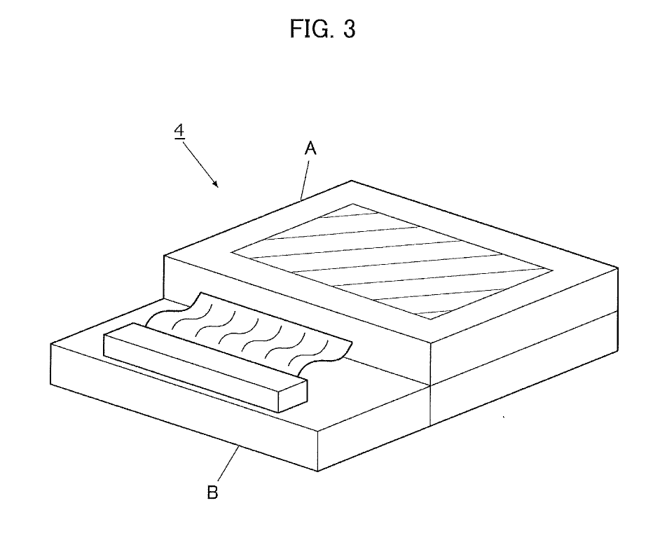

FIG. 3 is a schematic diagram showing an example of the display formed of the organic EL element. Luminescence of the organic EL element displays image information. For example, such image information includes a schematic diagram of a display of a mobile phone.

A display 4 includes a display unit A having a plurality of pixels, and a control unit B performing picture scanning of the display unit A based on the image information.

The control unit B is electrically connected to the display unit A. A scanning signal and an image data signal are transmitted to each of the plurality of pixels based on the image information from the outside, and the scanning signal makes each pixel per scanning line sequentially emit light corresponding to the image data signal to perform the image scanning, whereby the image information is displayed on the display unit A.

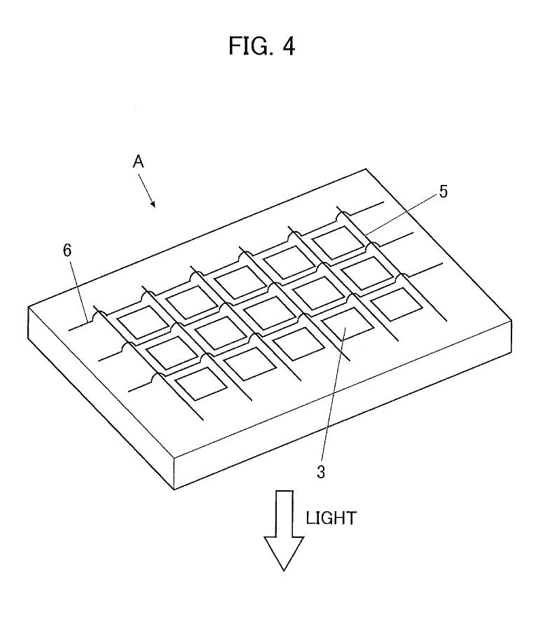

FIG. 4 is a schematic diagram showing the display A.

The display unit A includes a wiring unit including a plurality of scanning lines 5 and data lines 6, and a plurality of pixels 3 on the substrate. Main components of the display A will be described below.

FIG. 4 shows a state in which light emitted from the pixel 3 is extracted in the white arrow direction (i.e., downward direction).

The plurality of scanning lines 5 and data lines 6 in the wiring unit are made of a conductive material, respectively. The scanning lines 5 and the image data lines 6 orthogonally intersect each other in a lattice shape, and connected to the pixels 3 at the orthogonally crossing positions (note, the details are not shown).

When a scanning signal is applied to the pixel 3 through the scanning line 5, the pixel 3 receives an image data signal through the data line 6, thereby to emit light corresponding to the image data thus received.

Arranging a pixel with a red region of the luminescent color, a pixel with a green region, and a pixel with a blue region in parallel appropriately on the same substrate enables full color display.

Next, luminescent process of a pixel will be described specifically.

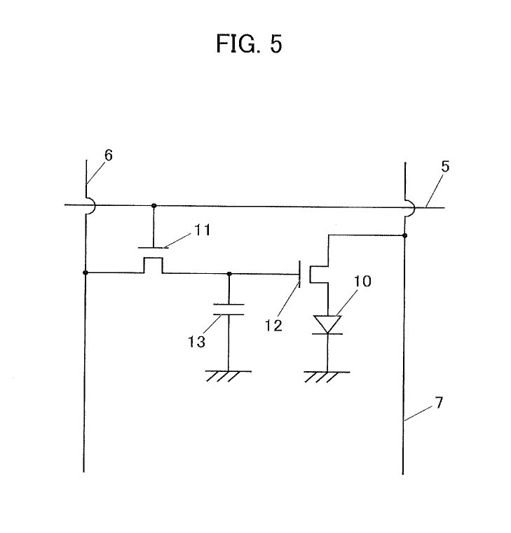

FIG. 5 is a circuit diagram of a pixel.

The pixel includes an organic EL element 10, a switching transistor 11, a drive transistor 12, and a condenser 13. As for a plurality of pixels, used are red luminescent, green luminescent and blue luminescent organic EL elements 10. Arranging those pixels in parallel on the same substrate realizes full color display.

In FIG. 5, an image data signal is applied to a drain of the switching transistor 11 from the control unit B through the data line 6. Then, when the scanning signal is applied to a gate of the switching transistor 11 from the control unit B through the scanning line 5, the switching transistor 11 starts a drive, and the image data signal thus applied to the drain is transmitted to the condenser 13 and gate of the drive transistor 12.

Transmitting the image data signal makes the condenser 13 charged corresponding to a potential of the image data signal and simultaneously the signal makes the drive transistor 12 start a drive. Here, a drain of the drive transistor 12 is connected to a power supply line 7, and a source thereof is connected to an electrode of the organic EL element 10. Thus, a current is supplied to the organic EL element 10 through the power supply line 7 corresponding to a potential of the image data signal thus applied to the gate.

When the sequential scanning of the control unit B moves on to the next scanning line 5, the switching transistor 11 stops a drive.

However, even when the switching transistor 11 stops a drive, the condenser 13 thus charged keeps a potential of the image data signal. Hereby, the drive transistor 12 is kept to drive, allowing luminescence of the organic EL element 10 to be continued until the next scanning signal is applied.

When the next scanning signal is applied via sequential scanning, the drive transistor 12 starts a drive corresponding to a potential of the next image data signal synchronized with the scanning signal. This process makes the organic EL element 10 emit light.

That is, as to luminescence of the organic EL element 10, the switching transistor 11 and the drive transistor 12 both of which serve as active elements are arranged in the respective organic EL elements 10 in the plurality of pixels, and this configuration makes the respective organic EL elements 10 in the plurality of pixels 3 emit light. This kind of luminescent system is called an active matrix system.

Here, luminescence of the organic EL element 10 may have a plurality of graduations generated by a multi-value image data signal having a plurality of grayscale potentials. Alternatively, luminescence of the organic EL element 10 may be on-off luminescence with a predetermined amount of luminescence caused by a binary image data signal. Further, the potential of the condenser 13 may be continuously kept until the next scanning signal is applied, or the condenser 13 may be discharged just before the next scanning signal is applied.

In the present invention, a luminescent system is not limited to the above described active matrix system. The luminescent system of the present invention may be driven by a passive matrix system via making the organic EL element emit light corresponding to a data signal only when a scanning signal is scanned.

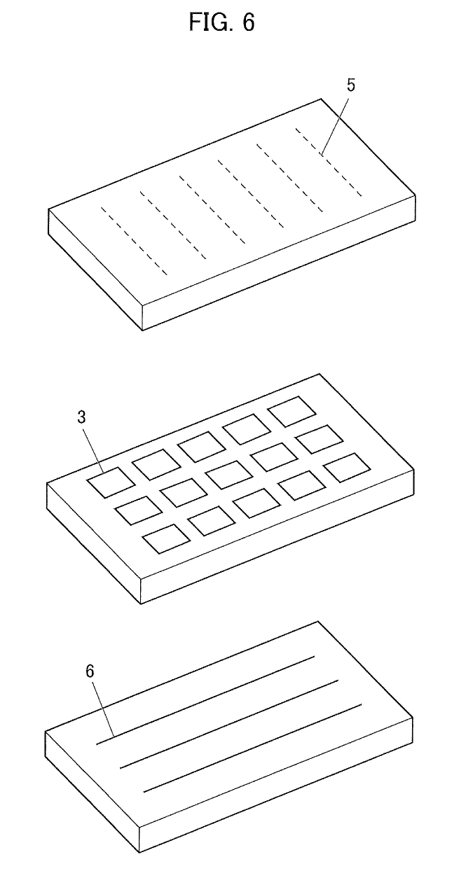

FIG. 6 is a schematic diagram showing a passive matrix type display. In FIG. 6, a plurality of scanning lines 5 are arranged facing each other via sandwiching pixels 3. Similarly, a plurality of image data lines 6 are arranged facing each other via sandwiching the pixels 3. Herein, the scanning lines 5 and the image data lines 6 are arranged in a lattice shape.

When a scanning signal of the scanning line 5 is applied via sequential scanning, a pixel 3 connected to the scanning line 5 thus having applied the scanning signal emits light corresponding to the image data signal.

In the passive matrix system, the pixel 3 has no active element, resulting in a decrease in the production cost.

Note, embodiments to which the present invention is applicable are not limited to the above described ones. Further, those embodiments of the present invention may be appropriately modified without departing from the spirit of the present invention.

### EXAMPLES

Hereinafter, the present invention will be described more specifically referring to Examples. However, the present invention is not limited to those Examples. Herein, a term of “part” or “%” is used in the Examples, while the term represents “part by mass” or “mass %” respectively unless otherwise noted.

Further, structures of the compounds used in the Examples are shown below. Herein, compounds other than those compounds are also described in the present specification. Note, the following compounds S-1, S-57 and H-441 are described in Japanese Unexamined Patent Application Publication No. 2014-179493, and compounds H-9 and H-219 are described in US Patent Application Publication No. 2013/0112952.

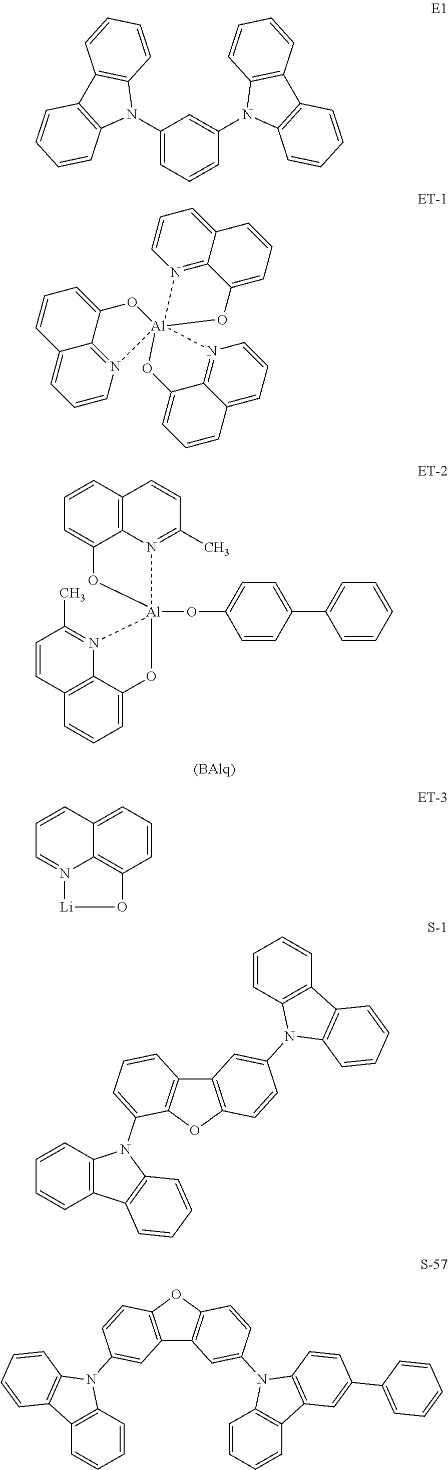

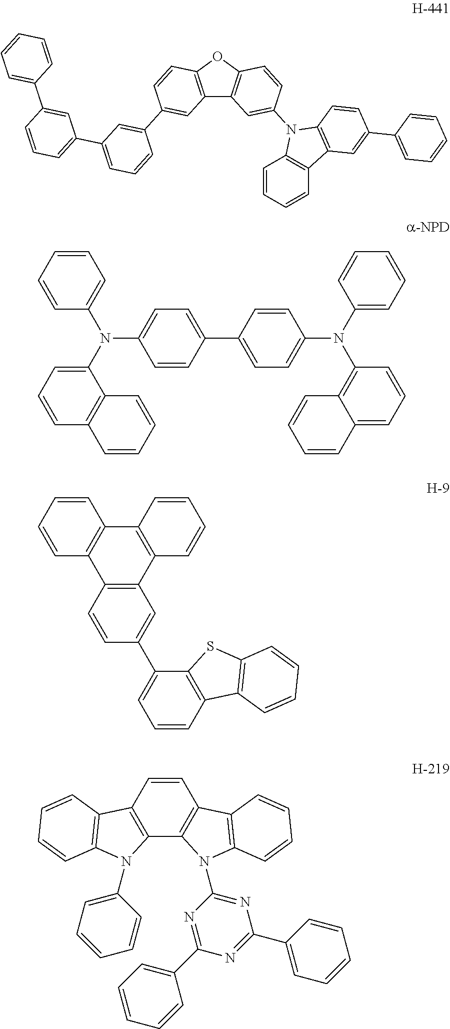 [SMILES: c1ccc(-c2cccc(-c3cccc(-c4ccc5oc6ccc(-n7c8ccccc8c8cc(-c9ccccc9)ccc87)cc6c5c4)c3)c2)cc1 ; c1ccc(N(c2ccc(-c3ccc(N(c4ccccc4)c4cccc5ccccc45)cc3)cc2)c2cccc3ccccc23)cc1 ; c1ccc2c(c1)sc1c(-c3ccc4c5ccccc5c5ccccc5c4c3)cccc12 ; c1ccc(-c2nc(-c3ccccc3)nc(-n3c4ccccc4c4ccc5c6ccccc6n(-c6ccccc6)c5c43)n2)cc1]

<<Preparation of Organic EL Element 1-1>>

(Formation of Anode)

On a glass substrate (NH Techno Glass Co., Ltd.) with a size of 100 mm×100 mm×1.1 mm, ITO (indium tin oxide) was deposited as an anode with a thickness of 100 nm. Then, the resulting transparent substrate provided with the ITO transparent electrode was subjected to ultrasonic cleaning, dried using a dry nitrogen gas, and subjected to UV ozone cleaning for 5 min.

(Formation of First Hole Transport Layer) On the resulting transparent substrate, a thin film was formed by a spin coating method using a solution prepared by diluting poly(3,4-ethylenedioxythiophene)-polystyrenesulfonate (PEDOT/PSS, Heraeus Holding, CLEVIOUS P VP Al 4083) with pure water to a concentration of 70%, under the conditions of 3000 rpm and 30 sec. After that, the resulting product was dried at 200° C. for 1 hr to provide a first hole transport layer having a thickness of 20 nm.

(Formation of Second Hole Transport Layer)

The resultant transparent substrate was held by a substrate holder of a commercially available vacuum deposition device. Then, MoO₃ serving as a hole transport material, E1 serving as an electron blocking material, 201a and 251b both serving as host compounds, and ET-1 serving as an electron transport material were separately put in molybdenum resistance heating boats at the respective amounts of 200 mg. D-6 serving as a luminescent dopant was put in another molybdenum resistance heating boat at the amount of 100 mg. Then, all the heating boats were attached to the vacuum deposition device.

Next, the vacuum chamber was decompressed to 4×10⁻⁴ Pa, and subsequently the heating boat filled with MoO₃ was heated via energization, thereby to provide a second hole transport layer with a thickness of 1 nm on the first hole transport layer at the deposition rate of 0.1 nm/sec.

(Formation of Electron Blocking Layer)

Next, for the formation of an electron blocking layer, the heating boat filled with E1 was heated via energization, to provide an electron blocking layer with a thickness of 10 nm on the second hole transport layer at the deposition rate of 0.1 nm/sec.

(Formation of Luminescent Layer)

Further, the heating boats respectively filled with 201a and 251b both serving as host compounds and the heating boat filled with D-6 serving as a luminescent dopant were heated via energization, to provide a luminescent layer with a thickness of 50 nm on the electron blocking layer via codeposition at the deposition rates of 0.028 nm/sec, 0.028 nm/sec and 0.01 nm/sec, respectively.

(Formation of Hole Blocking Layer)

Next, the heating boat filled with 251b that was a host compound B thus used for the formation of the luminescent layer was successively heated via energization, to provide a hole blocking layer with a thickness of 10 nm on the luminescent layer at the deposition rate of 0.1 nm/sec.

(Formation of Electron Transport Layer)

Further, the heating boat filled with ET-1 was heated via energization, to provide an electron transport layer having a thickness of 30 nm on the hole blocking layer via vapor deposition at the vapor deposition rate of 0.1 nm/sec. Herein, a temperature of the substrate was room temperature at the time of the vapor deposition.

(Formation of Cathode)

Then, lithium fluoride was vapor deposited to form a cathode buffer layer (i.e., an alkali metal compound buffer layer) with a thickness of 0.5 nm, and subsequently aluminum was vapor deposited to form a cathode with a thickness of 110 nm, whereby an organic EL element 1-1 of the Example was prepared.

<<Preparation of Organic EL Elements 1-2˜1-10>>

Organic EL elements 1-2˜1-10 were prepared the same as in the organic EL element 1-1 except that materials of the luminescent layers were changed to the compounds listed in Table 12, and the host compound B used in the luminescent layer was applied to the hole blocking layer.

Further, HOMO energy levels, LUMO energy levels, T₁ energies of the host compounds A and B were measured. Moreover, a phosphorescence maximum wavelength in a solution and a HOMO energy level of the phosphorescent compound were measured.

Here, the HOMO energy levels and the LUMO energy levels were calculated by using a molecular orbital calculation software (Gaussian 03, Revision D02, M. J. Frisch, et al., Gaussian Inc., Wallingford, Conn., 2004). Specifically, the energy levels (i.e., eV unit equivalent) of the host compounds A and B were calculated by using B3LYP/6-31G* as a keyword, and the energy levels (i.e., eV unit equivalent) of the phosphorescent compound were calculated by using B3LYP/LanL2DZ, and both subjected to structural optimization of the molecular structures thus targeted.

The T₁ energies of the host compounds A and B were calculated by subjected to exited state calculation of the Time-Dependent Density Functional Method.

The luminescence spectrum in the solution was measured by dissolving the dopant in 2-methyltetrahydrofuran and using Hitachi H-7000.

<<Evaluation of Organic EL Elements 1-1˜1-10>>

The samples thus prepared as mentioned above were sealed, and subjected to the following evaluations.

Note, in the sealing process, a non-luminescent surface of each organic EL element was covered by a glass case. By using a glass support substrate as a sealing substrate, an epoxy based photocurable adhesive (TOAGOSEI CO., LTD., LUXTRACK LC629B) serving as a sealing material was applied to a periphery of the glass case. Then, the glass case was covered over the cathode to be tightly fixed to the glass support substrate. UV light was irradiated from a side of the glass support substrate to cure the photocurable adhesive and seal every organic EL element. Hereby, a lighting device shown in FIGS. 1 and 2 were produced and evaluated in the following items.

(Evaluation in Lifetime of Element)

After completion of the vapor deposition, every element was sealed under nitrogen atmosphere. Then, every organic EL element was driven at a constant current affording initial brightness of 1000 cd/m², so as to measure a time that brightness decreased in ½ (500 cd/m²) of the initial brightness. The time thus measured was determined as an index of the halflife.

The scale of the halflife was represented by a relative value per value of the organic EL element 1-1 thus set to 100. It is shown that the higher the value is, the more excellent the lifetime is.

(Change in Voltage)

A voltage was measured by the current affording the initial brightness of 1000 cd/m², so as to measure a voltage rise (ΔV1) when the brightness became 50% of the initial one and obtain a ratio (ΔV1/V) of the voltage rise to the voltage (V) of the initial brightness. Then, a value of the organic EL element 1-10 was set to 100, and a relative value to the set value of the element 1-10 was determined to be a value representing a change in voltage after the element was driven.

Here, the smaller the calculated value is, the smaller the change in voltage after driven is. This phenomenon means a preferable state, demonstrating a small change in film quality of the element before and after the element is driven, a small change in balance of carrier injection and transport, and a preferable configuration of the element.

(Change in Externally Extracting Quantum Efficiency)

The element was turned on under the constant current condition of 2.5 mA/cm², and luminescent brightness (L1) [cd/m²] just after starting the lighting to calculate an externally extracting quantum efficiency (η1). Further, the element was similarly measured after measuring the lifetime, thereby to calculate an externally extracting quantum efficiency (η²) based on luminescent brightness (L2).

Here, the luminescent brightness was measured by using CS-1000 (Konica Minolta Sensing, Inc.)

A difference (η1-η2) between the externally extracting quantum efficiencies after evaluating an initial lifetime of the element was calculated. Then, a value of the organic EL element 1-10 was set to 100, and a relative value to the value of the element 1-10 was determined as a value representing a change in an externally extracting quantum efficiency

Here, it is shown that the smaller the calculated value is, the smaller the difference between the externally extracting quantum efficiencies is. This phenomenon means a preferable state, demonstrating a small change in film quality of the element before and after driving the element, a small change in balance of carrier injection and transport, and a preferable configuration of the element.

The results of the evaluation were listed in Table 12.

TABLE 12

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 1-1 | D-6 | 465 | −4.91 | 201a | 3.03 | −4.97 | −0.67 | 251b | 3.00 | −5.21 | −1.12 |
| 1-2 | D-6 | 465 | −4.91 | 202a | 3.14 | −5.24 | −0.62 | 252b | 3.10 | −5.80 | −1.20 |
| 1-3 | D-6 | 465 | −4.91 | 202a | 3.14 | −5.24 | −0.62 | 253b | 3.08 | −5.67 | −1.67 |
| 1-4 | D-6 | 465 | −4.91 | 203a | 3.09 | −5.17 | −1.15 | 254b | 3.00 | −5.50 | −1.68 |
| 1-5 | D-6 | 465 | −4.91 | 204a | 3.16 | −5.18 | −0.63 | 255b | 3.06 | −5.59 | −1.67 |
| 1-6 | D-6 | 465 | −4.91 | 204a | 3.16 | −5.18 | −0.63 | 256b | 3.10 | −5.70 | −1.19 |
| 1-7 | D-6 | 465 | −4.91 | 205a | 3.10 | −5.71 | −1.00 | 258b | 3.09 | −6.03 | −1.62 |
| 1-8 | D-6 | 465 | −4.91 | 206a | 3.08 | −5.70 | −1.04 | 259b | 3.07 | −5.91 | −1.50 |
| 1-9 | D-6 | 465 | −4.91 | 206a | 3.08 | −5.70 | −1.04 | 260b | 3.06 | −6.06 | −1.57 |
| 1-10 | D-6 | 465 | −4.91 | H-441 | 3.07 | −5.24 | −1.27 | S-1 | 3.05 | −5.38 | −1.42 |
| | | | | | | | | (Invention) | | | |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 1-1 | 50:50 | 0.24 | 0.45 | 0.30 | 119 | 85 | 87 | Invention |
| | | | 1-2 | 50:50 | 0.56 | 0.58 | 0.89 | 117 | 86 | 86 | Invention |
| | | | 1-3 | 60:40 | 0.43 | 1.05 | 0.76 | 115 | 90 | 86 | Invention |
| | | | 1-4 | 60:40 | 0.33 | 0.53 | 0.59 | 114 | 86 | 86 | Invention |
| | | | 1-5 | 50:50 | 0.41 | 1.04 | 0.68 | 113 | 90 | 86 | Invention |
| | | | 1-6 | 50:50 | 0.52 | 0.56 | 0.79 | 116 | 88 | 87 | Invention |
| | | | 1-7 | 50:50 | 0.32 | 0.62 | 1.12 | 118 | 85 | 82 | Invention |
| | | | 1-8 | 50:50 | 0.21 | 0.46 | 1.00 | 121 | 86 | 83 | Invention |
| | | | 1-9 | 50:50 | 0.36 | 0.53 | 1.15 | 120 | 86 | 84 | Invention |
| | | | 1-10 | 50:50 | 0.14 | 0.15 | 0.47 | 100 | 100 | 100 | Comparative |

Table 12 shows that the organic EL elements 1-1˜1-9 of the present invention have longer lifetimes, smaller changes in voltage and smaller changes in the externally extracting quantum efficiency before and after driving the elements than the organic EL element 1-10 in Comparative Example. Accordingly, it is determined that the properties of the elements of the present invention are improved.

### Example 2

<<Preparation of Organic EL Elements 2-1˜2-4>>

The organic EL elements 2-1˜2-4 were prepared the same as in the organic EL element 1-1 except that a material of every luminescent layer was changed to a compound listed in Table 13 shown later, the host compound B used for the luminescent layer was applied to the hole blocking layer, and a material of every electron blocking layer was changed from E1 to α-NPD. Finally, all the elements were sealed. Then, the elements thus prepared were evaluated the same as in Example 1, and the results were shown as relative values to the value of the organic EL element 2-4 thus set to 100.

The results of the evaluation were listed in Table 13.

TABLE 13

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 2-1 | D-12 | 485 | −4.82 | 301a | 3.08 | −5.23 | −1.26 | 351b | 3.10 | −5.46 | −1.55 |
| 2-2 | D-12 | 485 | −4.82 | 303a | 3.06 | −5.35 | −1.23 | 352b | 3.07 | −5.79 | −1.47 |
| 2-3 | D-12 | 485 | −4.82 | 304a | 3.07 | −5.34 | −1.21 | 353b | 3.08 | −5.79 | −1.46 |
| 2-4 | D-12 | 485 | −4.82 | H-441 | 3.07 | −5.24 | −1.27 | S-1 | 3.05 | −5.38 | −1.42 |
| | | | | | | | | (Invention | | | |
| | | | | | | | | 401a) | | | |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 2-1 | 50:50 | 0.23 | 0.29 | 0.64 | 115 | 85 | 85 | Invention |
| | | | 2-2 | 50:50 | 0.44 | 0.24 | 0.97 | 118 | 82 | 82 | Invention |
| | | | 2-3 | 50:50 | 0.45 | 0.25 | 0.97 | 120 | 82 | 82 | Invention |
| | | | 2-4 | 50:50 | 0.14 | 0.15 | 0.56 | 100 | 100 | 100 | Comparative |

Table 13 demonstrates that the organic EL elements 2-1˜2-3 of the present invention have longer lifetimes, smaller changes in voltage and smaller changes in the externally extracting quantum efficiency before and after driving the elements than the organic EL element 2-4 in Comparative Example. Accordingly, it is determined that the properties of the elements of the present invention are improved.

### Example 3

<<Preparation of Organic EL Elements 3-1˜3-16>>

The organic EL elements 3-1˜3-16 were prepared the same as in the organic EL element 1-1 except that a material of every luminescent layer was changed to a compound listed in Table 14 shown later, the host compound B used for the luminescent layer was applied to the hole blocking layer, a material of every electron blocking layer was changed from E1 to α-NPD, a material of every electron transport layer were changed from ET-1 to ET-1 and ET-3 at the rate of 1:1, and a thickness of every electron transport layer was changed to 30 nm. Finally all the elements were sealed. Then, the elements thus prepared were evaluated the same as in Example 1, and the results were shown as relative values to the value of the organic EL element 3-15 thus set to 100.

The results of the evaluation were listed in Table 14.

TABLE 14

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 3-1 | D-1 | 464 | −4.83 | 401a | 3.05 | −5.83 | −1.42 | 451b | 3.03 | −5.55 | −1.64 |
| 3-2 | D-1 | 464 | −4.83 | 401a | 3.05 | −5.83 | −1.42 | 451b | 3.03 | −5.55 | −1.64 |
| 3-3 | D-1 | 464 | −4.83 | 401a | 3.05 | −5.83 | −1.42 | 451b | 3.03 | −5.55 | −1.64 |
| 3-4 | D-1 | 464 | −4.83 | 401a | 3.05 | −5.83 | −1.42 | 451b | 3.03 | −5.55 | −1.64 |
| 3-5 | D-1 | 464 | −4.83 | 401a | 3.05 | −5.83 | −1.42 | 451b | 3.03 | −5.55 | −1.64 |
| 3-6 | D-1 | 464 | −4.83 | 401a | 3.05 | −5.83 | −1.42 | 451b | 3.03 | −5.55 | −1.64 |
| 3-7 | D-1 | 464 | −4.83 | 401a | 3.05 | −5.83 | −1.42 | 451b | 3.03 | −5.55 | −1.64 |
| 3-8 | D-1 | 464 | −4.83 | 401a | 3.05 | −5.83 | −1.42 | 452b | 2.99 | −5.65 | −1.85 |
| 3-9 | D-1 | 464 | −4.83 | 402a | 3.00 | −5.19 | −1.35 | 453b | 3.07 | −5.51 | −1.66 |
| 3-10 | D-1 | 464 | −4.83 | 401a | 3.05 | −5.83 | −1.42 | 454b | 3.01 | −5.58 | −1.71 |
| 3-11 | D-1 | 464 | −4.83 | 401a | 3.05 | −5.83 | −1.42 | 456b | 3.00 | −5.64 | −1.81 |
| 3-12 | D-1 | 464 | −4.83 | 403a | 3.13 | −5.83 | −1.44 | 457b | 3.12 | −5.94 | −1.89 |
| 3-13 | D-1 | 464 | −4.83 | 404a | 3.12 | −5.40 | −1.48 | 457b | 3.12 | −5.94 | −1.89 |
| 3-14 | D-1 | 464 | −4.83 | 405a | 3.06 | −5.35 | −1.23 | 458b | 3.07 | −5.79 | −1.47 |
| 3-15 | D-1 | 464 | −4.83 | H-441 | 3.07 | −5.24 | −1.27 | S-1 | 3.05 | −5.38 | −1.42 |
| | | | | | | | | (Invention | | | |
| 3-16 | D-1 | 464 | −4.83 | H-441 | 3.07 | −5.24 | −1.27 | S-57 | 3.08 | −5.30 | −1.47 |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 3-1 | 50:50 | 0.17 | 0.22 | 0.72 | 125 | 78 | 76 | Invention |
| | | | 3-2 | 30:70 | 0.17 | 0.22 | 0.72 | 120 | 84 | 80 | Invention |
| | | | 3-3 | 15:85 | 0.17 | 0.22 | 0.72 | 115 | 90 | 83 | Invention |
| | | | 3-4 | 5:95 | 0.17 | 0.22 | 0.72 | 105 | 92 | 90 | Invention |
| | | | 3-5 | 70:30 | 0.17 | 0.22 | 0.72 | 120 | 88 | 80 | Invention |
| | | | 3-6 | 85:15 | 0.17 | 0.22 | 0.72 | 110 | 88 | 84 | Invention |
| | | | 3-7 | 95:5 | 0.17 | 0.22 | 0.72 | 108 | 92 | 92 | Invention |
| | | | 3-8 | 60:40 | 0.27 | 0.43 | 0.82 | 120 | 82 | 78 | Invention |
| | | | 3-9 | 60:40 | 0.32 | 0.31 | 0.68 | 120 | 84 | 80 | Invention |
| | | | 3-10 | 50:50 | 0.20 | 0.29 | 0.75 | 113 | 88 | 84 | Invention |
| | | | 3-11 | 50:50 | 0.26 | 0.39 | 0.81 | 115 | 88 | 84 | Invention |
| | | | 3-12 | 50:50 | 0.56 | 0.45 | 1.11 | 120 | 80 | 78 | Invention |
| | | | 3-13 | 50:50 | 0.54 | 0.41 | 1.11 | 118 | 88 | 80 | Invention |
| | | | 3-14 | 50:50 | 0.44 | 0.24 | 0.96 | 123 | 84 | 80 | Invention |
| | | | 3-15 | 50:50 | 0.14 | 0.15 | 0.55 | 100 | 100 | 100 | Comparative |
| | | | 3-16 | 50:50 | 0.06 | 0.20 | 0.47 | 105 | 100 | 100 | Comparative |

Table 14 demonstrates that the organic EL elements 3-1˜3-14 of the present invention have longer lifetimes, smaller changes in voltage and smaller changes in the externally extracting quantum efficiency before and after driving the elements than the organic EL elements 3-15 and 3-16 in Comparative Examples. Accordingly, it is determined that the properties of the elements of the present invention are improved.

### Example 4

<<Preparation of Organic EL Elements 4-1˜4-6>>

The organic EL elements 4-1˜4-6 were prepared the same as in the organic EL element 1-1 except that a material of every luminescent layer was changed to a compound listed in Table 15 shown later, a thickness of every luminescent layer was changed from 50 nm to 30 nm, the host compound B used for the luminescent layer was applied to the hole blocking layer, a material of every electron transport layer were changed from ET-1 to ET-1 and ET-3 at the rate of 1:1, and a thickness of every electron transport layer was changed to 30 nm. Finally all the elements were sealed. Then, the elements thus prepared were evaluated the same as in Example 1, and the results were shown as relative values to the value of the organic EL element 4-6 thus set to 100.

The results of the evaluation were listed in Table 15.

TABLE 15

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 4-1 | D-13 | 466 | −4.33 | 501a | 2.78 | −5.26 | −1.87 | 551b | 2.84 | −5.62 | −2.07 |
| 4-2 | D-13 | 466 | −4.33 | 501a | 2.78 | −5.26 | −1.87 | 552b | 2.82 | −5.53 | −2.12 |
| 4-3 | D-13 | 466 | −4.33 | 501a | 2.78 | −5.26 | −1.87 | 553b | 2.86 | −5.89 | −2.90 |
| 4-4 | D-13 | 466 | −4.33 | 501a | 2.78 | −5.26 | −1.87 | 554b | 2.81 | −5.55 | −2.03 |
| 4-5 | D-13 | 466 | −4.33 | 502a | 2.92 | −5.10 | −0.85 | 555b | 2.78 | −6.03 | −2.55 |
| 4-6 | D-13 | 466 | −4.33 | Comparative | 2.78 | −5.26 | −1.87 | Comparative | 2.77 | −5.60 | −1.23 |
| | | | | Cmpd | | | | Cmpd | | | |
| | | | | H-219 | | | | | | | |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 4-1 | 50:50 | 0.36 | 0.20 | 1.29 | 116 | 88 | 87 | Invention |
| | | | 4-2 | 50:50 | 0.27 | 0.25 | 1.20 | 120 | 85 | 82 | Invention |
| | | | 4-3 | 50:50 | 0.63 | 0.43 | 1.56 | 110 | 85 | 85 | Invention |
| | | | 4-4 | 50:50 | 0.29 | 0.16 | 1.22 | 118 | 88 | 82 | Invention |
| | | | 4-5 | 50:50 | 0.93 | 1.70 | 1.70 | 110 | 90 | 90 | Invention |
| | | | 4-6 | 50:50 | 0.34 | −0.64 | 1.27 | 100 | 100 | 100 | Comparative |

Table 15 demonstrates that the organic EL elements 4-1˜4-5 of the present invention have longer lifetimes, smaller changes in voltage and smaller changes in the externally extracting quantum efficiency before and after driving the elements than the organic EL element 4-6 in Comparative Example. Accordingly, it is determined that the properties of the elements of the present invention are improved.

### Example 5

<<Preparation of Organic EL Elements 5-1˜5-6>>

The organic EL elements 5-1˜5-6 were prepared the same as in the organic EL element 1-1 except that a material of every luminescent layer was changed to a compound listed in Table 16 shown later, the host compound B used for the luminescent layer was applied to the hole blocking layer, a material of every electron transport layer was changed from ET-1 to ET-2, and finally all the element were sealed. Then, the elements thus prepared were evaluated the same as in Example 1, and the results were shown as relative values to the value of the organic EL element 4-6 thus set to 100.

The results of the evaluation were listed in Table 16.

TABLE 16

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 5-1 | D-10 | 463 | −4.52 | 601a | 3.15 | −4.78 | −0.56 | 651b | 3.39 | −6.55 | −1.02 |
| 5-2 | D-10 | 463 | −4.52 | 601a | 3.15 | −4.78 | −0.56 | 652b | 2.68 | −5.07 | −1.66 |
| 5-3 | D-10 | 463 | −4.52 | 601a | 3.15 | −4.78 | −0.56 | 653b | 2.13 | −4.99 | −2.29 |
| 5-4 | D-10 | 463 | −4.52 | 601a | 3.15 | −4.78 | −0.56 | 654b | 3.08 | −4.97 | −1.00 |
| 5-5 | D-10 | 463 | −4.52 | 602a | 2.79 | −4.87 | −1.51 | 655b | 2.60 | −5.08 | −1.88 |
| 5-6 | D-10 | 463 | −4.52 | H-441 | 3.07 | −5.24 | −1.27 | S-1 | 3.05 | −5.38 | −1.42 |
| | | | | | | | | (Invention | | | |
| | | | | | | | | 401a) | | | |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 5-1 | 50:50 | 1.77 | 0.46 | 2.03 | 110 | 86 | 90 | Invention |
| | | | 5-2 | 50:50 | 0.29 | 1.10 | 0.55 | 110 | 86 | 80 | Invention |
| | | | 5-3 | 50:50 | 0.21 | 1.73 | 0.47 | 110 | 86 | 80 | Invention |
| | | | 5-4 | 50:50 | 0.19 | 0.44 | 0.45 | 123 | 85 | 80 | Invention |
| | | | 5-5 | 50:50 | 0.21 | 0.37 | 0.56 | 118 | 80 | 80 | Invention |
| | | | 5-6 | 50:50 | 0.14 | 0.15 | 0.86 | 100 | 100 | 100 | Comparative |

Table 16 demonstrates that the organic EL elements 5-1˜5-5 of the present invention have longer lifetimes, smaller changes in voltage and smaller changes in the externally extracting quantum efficiency before and after driving the elements than the organic EL element 5-6 in Comparative Example. Accordingly, it is determined that the properties of the elements are improved.

### Example 6

<<Preparation of Organic EL Elements 6-1˜6-8>>

The organic EL elements 6-1˜6-8 were prepared the same as in the organic EL element 1-1 except that a material of every luminescent layer was changed to a compound listed in Table 17 shown later, the host compound B used for the luminescent layer was applied to the hole blocking layer, a material of every electron transport layer was changed from ET-1 to ET-1 and ET-3 at the rate of 1:1, and a thickness of every electron transport layer was changed to 30 nm. Finally all the elements were sealed. Then, the elements thus prepared were evaluated the same as in Example 1, and the results were shown as relative values to the value of the organic EL element 6˜8 thus set to 100.

The results of the evaluation were listed in Table 17.

TABLE 17

| | Phosphorescent | | | | | | | | | | |
|---|---|---|---|---|---|---|---|---|---|---|---|
| | Compound | | | Host Compound A | | | | Host Compound B | | | |
| Organic | | | HOMO | | | HOMO | LUMO | | | HOMO | LUMO |
| EL | | | Energy | | T₁ | Energy | Energy | | T₁ | Energy | Energy |
| Element | Cmpd | λ max | Level | Cmpd | Energy | Level | Level | Cmpd | Energy | Level | Level |
| No. | No. | (nm) | (eV) | No. | (eV) | (eV) | (eV) | No. | (eV) | (eV) | (eV) |
| 6-1 | D-3 | 465 | −4.92 | 701a | 2.86 | −6.11 | −1.87 | 751b | 2.90 | −6.57 | −2.14 |
| 6-2 | D-3 | 465 | −4.92 | 701a | 2.86 | −6.11 | −1.87 | 752b | 2.80 | −6.28 | −2.37 |
| 6-3 | D-3 | 465 | −4.92 | 701a | 2.86 | −6.11 | −1.87 | 753b | 2.77 | −6.32 | −2.55 |
| 6-4 | D-3 | 465 | −4.92 | 702a | 2.86 | −5.91 | −1.83 | 754b | 2.90 | −6.57 | −2.14 |
| 6-5 | D-3 | 465 | −4.92 | 702a | 2.86 | −5.91 | −1.83 | 755b | 2.85 | −6.20 | −1.95 |
| 6-6 | D-3 | 465 | −4.92 | 702a | 2.86 | −5.91 | −1.83 | 756b | 2.84 | −6.16 | −1.89 |
| 6-7 | D-3 | 465 | −4.92 | 702a | 2.86 | −5.91 | −1.83 | 757b | 2.83 | −6.19 | −1.99 |
| 6-8 | D-3 | 465 | −4.92 | H-441 | 3.07 | −5.24 | −1.27 | S-1 | 3.05 | −5.38 | −1.42 |
| | | | | | | | | (Invention | | | |
| | | | | | | | | 401a) | | | |
| | | | | | | | | | Change in | | |
| | | | Organic | | | | Δ HOMO | | External | | |
| | | | EL | | Δ HOMO | Δ LUMO | (Phos | | Extracting | | |
| | | | Element | A:B | (Cmpd A- | (Cmpd A- | Cmpd- | Element | Quantum | Voltage | |
| | | | No. | Ratio | Cmpd B) | Cmpd B) | Cmpd B) | Lifetime | Efficiency | Change | Note |
| | | | 6-1 | 50:50 | 0.46 | 0.27 | 1.65 | 120 | 84 | 87 | Invention |
| | | | 6-2 | 50:50 | 0.17 | 0.50 | 1.36 | 118 | 85 | 85 | Invention |
| | | | 6-3 | 50:50 | 0.21 | 0.68 | 1.40 | 118 | 85 | 85 | Invention |
| | | | 6-4 | 50:50 | 0.66 | 0.31 | 1.65 | 115 | 82 | 87 | Invention |
| | | | 6-5 | 50:50 | 0.29 | 0.12 | 1.28 | 114 | 85 | 84 | Invention |
| | | | 6-6 | 50:50 | 0.25 | 0.06 | 1.24 | 113 | 87 | 84 | Invention |
| | | | 6-7 | 50:50 | 0.28 | 0.16 | 1.27 | 115 | 84 | 84 | Invention |
| | | | 6-8 | 50:50 | 0.14 | 0.15 | 0.46 | 100 | 100 | 100 | Comparative |

Table 17 demonstrates that the organic EL elements 6-1˜6-7 of the present invention have longer lifetimes, smaller changes in voltage and smaller changes in the externally extracting quantum efficiency before and after driving the elements than the organic EL element 6-8 in Comparative Example. Accordingly, it is determined that the properties of the elements of the present invention are improved.

### DESCRIPTION OF REFERENCE NUMERALS

3: Pixel
4: Display
5: Scanning Line
6: Data Line
7: Power Source line
10: Organic EL Element
11: Switching Transistor
12: Drive Transistor
13: Condenser
101: Organic EL Element
102: Glass Case (Cover)
105: Cathode
106: (Multiple) Organic Layer(s)
107: Glass Substrate provided with Transparent Electrode
108: Nitrogen Gas
109: Moisture Capture
A: Display Unit
B: Control Unit

1. An organic electroluminescent element comprising:
a luminescent layer sandwiched between an anode and a cathode, and
a plurality of organic layers including the luminescent layer, wherein
the luminescent layer contains a phosphorescent compound, and host compounds A and B both satisfying the following Equations and Requirement (11).
Host Compound A=X+nR₁
Host Compound B=X+mR₂
(in Equations, X has a structure formed via linking a plurality of aromatic cyclic groups, and represents a structure having the same linking positions; The aromatic cyclic group means an aromatic hydrocarbon cyclic group or an aromatic heterocyclic group;
X of the host compound A has a structure the same as of X of the host compound B;
R₁ represents a hydrogen atom, a phenyl group optionally having a substituent, or an alkyl group optionally having a substituent;
R₂ represents an electron withdrawing group, or a 5-membered or a 6-membered nitrogen-containing heterocyclic group;
“n” represents 0 or an integer of 1˜4, and when “n” is 0, R₁ represents a hydrogen atom; and
“m” represents an integer of 1˜4); and
[HOMO Energy Level of Host Compound A]−[HOMO Energy Level of Host Compound B]≥0.15 eV. (11):

2. The organic electroluminescent element described in claim 1, wherein X includes a structures represented by the following General Formulae (2)˜(7). 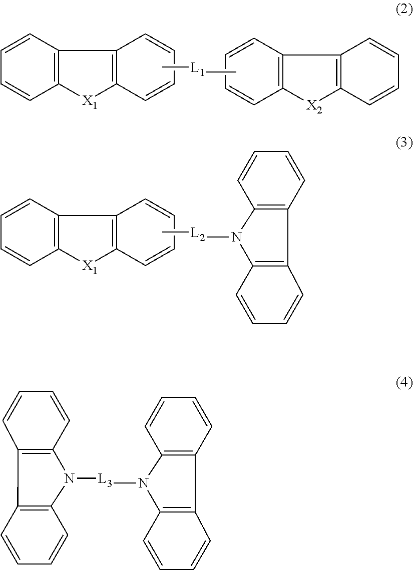
(In General Formulae (2)˜(4), X₁ and X₂ independently represent any one of an oxygen atom, a sulfur atom and a nitrogen atom; When X₁ and/or X₂ represent a nitrogen atom, X₁ and/or X₂ representing a nitrogen atom have a substituent; and L₁, L₂ and L₃ represent linkers, respectively); 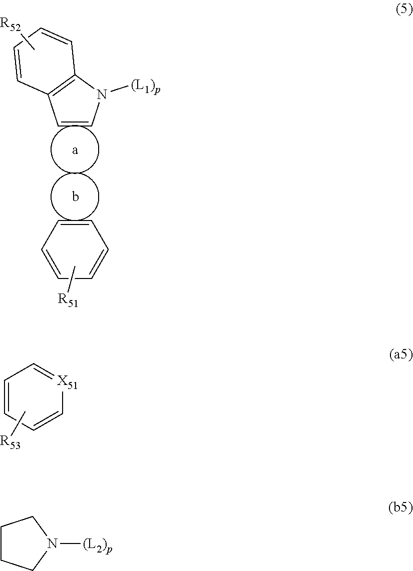
(In General Formula (5), “Ring a” represents an aromatic ring or a heterocyclic ring both represented by Formula (a5) fused at optional positions of adjacent 2 rings; X₅₁ represents C—R or a nitrogen atom;
“Ring b” represents a heterocyclic ring represented by Formula (b5) fused at optional positions to adjacent 2 rings;
L₁ and L₂ independently represent a C6˜22 aromatic hydrocarbon cyclic group, a C3˜16 aromatic heterocyclic group or a group thus formed via linkage of the 2˜10 cyclic groups; The aromatic hydrocarbon cyclic group and aromatic heterocyclic group in L₁ and L₂ may have a substituent;
“p” represents an integer of 0˜7. When “p” is 2 or more, L₁(s) may be the same or different respectively, and L₂(s) may be the same or different each other; and
R, R₅₁˜R₅₃ independently represent a hydrogen atom, a C1˜20 alkyl group, a C7˜38 aralkyl group, a C2˜20 alkenyl group, a C2˜20 alkynyl group, a C2˜40 dialkylamino group, a C12˜44 diarylamino group, a C14˜76 diaralkylamino group, a C2˜20 acyl group, a C2˜20 acyloxy group, a C1˜20 alkoxy group, a C2˜20 alkoxycarbonyl group, a C2˜20 alkoxycarbonyloxy group, a C1˜20 alkylsulfonyl group, a C6˜22 aromatic hydrocarbon cyclic group, or a C3˜16 aromatic heterocyclic group, and each of those groups may have a substituent); 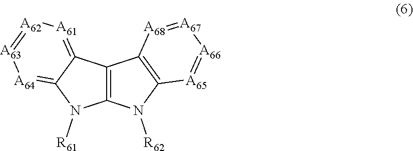
(In General Formula (6), A₆₁˜A₆₈ independently represent C—Rx or a nitrogen atom, and a plurality of Rx(s) may be the same or different each other; The plurality of Rx(s) independently represent a hydrogen atom or the same meaning as the substituent in General Formulae (2)˜(4); and R₆₁ and R₆₂ independently represent the same meaning as Rx); and 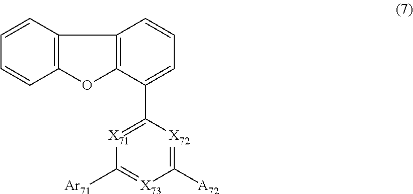
(In General Formula (7), X₇₁, X₇₂ and X₇₃ independently represent C—R′ or a nitrogen atom, and at least one of X₇₁, X₇₂ and X₇₃ is a nitrogen atom; R′, Ar₇₁ and Ar₇₂ independently represent a hydrogen atom, a substituted or non-substituted C1˜12 alkyl group, or a substituted or non-substituted C6˜30 aryl group where the number of ring forming carbon atoms is 6˜30, and there is no case that all of R′, Ar₇₁ and Ar₇₂ simultaneously represent a hydrogen atom).

3. The organic electroluminescent element described in claim 1, wherein R₂ represents an electron withdrawing group, a 5-membered or a 6-membered nitrogen-containing aromatic heterocyclic group.

4. The organic electroluminescent element described in claim 1, wherein the host compounds A and B satisfy the following Requirements (12) and (13).
Excited Triplet State Energies of Host Compounds A and B(T₁ Energies)≥3.0 eV; and (12):
[LUMO Energy Level of Host Compound A]−[LUMO Energy Level of Host Compound B]≥0.15 eV. (13):

5. The organic electroluminescent element described in claim 1, comprising the phosphorescent compound and the host compounds A and B all of which satisfy the following Requirements (14)˜(16).
A luminescence maxim wavelength of luminescence spectrum in a solution of the phosphorescent compound is 470 nm or less; (14):
[HOMO Energy Level of Phosphorescent Compound]−[HOMO Energy Level of Host Compound B]≥0.35 eV; and (15):
A ratio of the host compound A to the host compound B is in the range of 10:90˜90:10. (16):

6. A display provided with the organic electroluminescent element described in claim 1.

7. A lighting device provided with the organic electroluminescent element described in claim 1.
